(19) United States
(12) Patent Application Publication
(10) Pub. No.: US 2015/0115251 A1
(43) Pub. Date: Apr. 30, 2015

(54) DISPLAY DEVICE AND ELECTRONIC APPARATUS

(71) Applicant: Sony Corporation, Tokyo (JP)

(72) Inventors: Seiichiro Jinta, Kanagawa (JP); Seonghee Noh, Kanagawa (JP)

(21) Appl. No.: 14/498,108

(22) Filed: Sep. 26, 2014

(30) Foreign Application Priority Data
Oct. 30, 2013 (JP) 2013-225533

(51) Int. Cl. H01L 51/52; H01L 27/32

(52) U.S. Cl. CPC H01L 51/5234; H01L 51/5218; H01L 27/3244
USPC 257/40

(57) ABSTRACT

Provided is a display device, including: a first electrode; an organic layer that is provided on the first electrode and includes a light-emission layer; and a second electrode that includes a first conductive film and a second conductive film, the first conductive film and the second conductive film being laminated in order on the organic layer.

### CROSS REFERENCE TO RELATED APPLICATIONS

This application claims the benefit of Japanese Priority Patent Application JP 2013-225533 filed on Oct. 30, 2013, the entire contents of which are incorporated herein by reference.

### BACKGROUND

The present disclosure relates to a display device such as an organic EL (electroluminescence) display device, and to an electronic apparatus that includes the display device.

In recent years, in a field of display devices that perform image display, there has been developed and commercialized a display device (an organic EL display device) that uses, as a light-emission element, a current-driven optical element in which light-emission luminance is varied in response to a value of a flowing current, e.g., an organic EL element. Unlike a liquid crystal element, the light-emission element is a spontaneous light-emission element, and therefore an additional light source (a backlight) may be eliminated. Accordingly, the organic EL display device enjoys features such as high image visibility, low power consumption, and high response speed of the elements, compared to a liquid crystal display device accompanied with a light source.

Since such a display device has a configuration in which a light-emission layer (an organic electroluminescent layer) is interposed between electrodes (an anode and a cathode), an intrusion of a foreign matter into the organic layer during a manufacturing process may cause occurrence of a short-circuited path between the electrodes, which may lead to degradation in image quality. Thus, a repair technique of disconnecting the short-circuited path is proposed (for example, Japanese Unexamined Patent Application Publication No. 2005-340149).

### SUMMARY

The method proposed in Japanese Unexamined Patent Application Publication No. 2005-340149 involves applying a reverse bias voltage between the electrodes to destroy or insulate the short-circuited portion. However, depending on a material or a thickness of the electrodes, the repair may be difficult in some cases. Hence, there has been a desire for an element structure capable of reducing an electrical influence due to an intrusion of a foreign matter and improving image quality.

It is desired to provide a display device that makes it possible to improve display image quality, and an electronic apparatus.

According to an embodiment (1) of the present disclosure, there is provided a display device including: a first electrode; an organic layer that is provided on the first electrode and includes a light-emission layer; and a second electrode that includes a first conductive film and a second conductive film, the first conductive film and the second conductive film being laminated in order on the organic layer.

According to an embodiment of the present disclosure, there is provided an electronic apparatus provided with a display device. The display device includes: a first electrode; an organic layer that is provided on the first electrode and includes a light-emission layer; and a second electrode that includes a first conductive film and a second conductive film, the first conductive film and the second conductive film being laminated in order on the organic layer.

In the display device according to the above-described embodiment (1) of the present disclosure and the electronic apparatus according to the above-described embodiment of the present disclosure, the second electrode includes the first conductive film and the second conductive film that are laminated in order on the organic layer. Thereby, during a manufacturing process, in a case of occurrence of a short-circuited path between the first electrode and the second electrode due to a foreign matter, the short-circuited path is allowed to be readily electrically-disconnected, and resistance of the second electrode is allowed to be easily lowered.

According to an embodiment (2) of the present disclosure, there is provided a display device including: a first electrode; an organic layer that is provided on the first electrode and includes a light-emission layer; and a second electrode that is provided on the organic layer and includes a local portion having higher resistance than that of another portion.

In the display device according to the above-described embodiment (2) of the present disclosure, the second electrode includes the local portion having higher resistance than that of another portion. Thus, during a manufacturing process, the short-circuited path between the first electrode and the second electrode due to a foreign matter is allowed to be readily electrically-disconnected, and resistance of the second electrode is allowed to be easily lowered.

According to the display device in the above-described embodiment (1) of the present disclosure and the electronic apparatus in the above-described embodiment of the present disclosure, the second electrode includes the first conductive film and the second conductive film that are laminated in order on the organic layer. It is therefore possible to reduce an electrical influence of a foreign matter and to allow resistance of the second electrode to be easily lowered. This makes it possible to improve image quality.

According to the display device in the above-described embodiment (2) of the present disclosure, the second electrode includes the local portion having higher resistance than that of another portion. It is therefore possible to reduce an electrical influence of a foreign matter and to allow resistance of the second electrode to be easily lowered. This makes it possible to improve image quality.

It is to be noted that the contents above are an example of the present disclosure. Effects of the present disclosure are not limited to those described above, and may be other different effects, or may further include other effects.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 illustrates a configuration of a display device according to an embodiment of the present disclosure.

FIG. 2 is a circuit diagram illustrating one example of a pixel drive circuit illustrated in FIG. 1.

FIG. 3 is a cross-sectional view illustrating a configuration of the display device illustrated in FIG. 1.

FIG. 4 schematically illustrates a subpixel layout illustrated in FIG. 1.

FIG. 5 schematically illustrates layouts of a color filter layer, an organic layer (a light-emission layer), and bank apertures that constitute the pixel layout illustrated in FIG. 4.

FIG. 6A is a schematic cross-sectional view illustrating an example of a tandem configuration of an organic layer illustrated in FIG. 3.

FIG. 6B is a schematic cross-sectional view illustrating an example of a tandem configuration of the organic layer illustrated in FIG. 3.

FIG. 7A is a cross-sectional view illustrating a configuration of an organic EL element (without a foreign matter) illustrated in FIG. 3.

FIG. 7B is a cross-sectional view illustrating a configuration of an organic EL element (in a vicinity of a region where a foreign matter intrudes) illustrated in FIG. 3.

FIG. 8A is an enlarged cross-sectional view illustrating an example of a second electrode illustrated in FIG. 3.

FIG. 8B is an enlarged cross-sectional view illustrating an example of a second electrode illustrated in FIG. 3.

FIG. 9 is a flowchart illustrating a flow of a manufacturing process of the display device illustrated in FIG. 3.

FIG. 10A is a cross-sectional view illustrating a process of forming the second electrode in the manufacturing process of the display device illustrated in FIG. 9.

FIG. 10B is a cross-sectional view illustrating a process following FIG. 10A.

FIG. 10C is a cross-sectional view illustrating a process following FIG. 10B.

FIG. 11 is a functional block diagram illustrating an example of a system configuration including a repair device used in the manufacturing process illustrated in FIG. 9.

FIG. 12 is a functional block diagram illustrating a configuration of the repair device illustrated in FIG. 11, together with the pixel drive circuit.

FIG. 13A is a circuit diagram illustrating a state of the pixel drive circuit and so on in display operation.

FIG. 13B is a circuit diagram illustrating a state of the pixel drive circuit and so on in normal light-emission.

FIG. 13C is a circuit diagram illustrating a state of the pixel drive circuit and so on in failure of normal light-emission (with an intrusion of a foreign matter).

FIG. 13D is a circuit diagram illustrating a state of the pixel drive circuit and so on in repair operation.

FIG. 14 illustrates an example of a drive condition of a bias voltage in the repair operation.

FIG. 15A schematically illustrates an example of a method of energizing a panel in the repair operation.

FIG. 15B schematically illustrates an example of a method of energizing a panel in the repair operation.

FIG. 15C schematically illustrates an example of a method of energizing a panel in the repair operation.

FIG. 15D schematically illustrates an example of a method of energizing a panel in the repair operation.

FIG. 15E schematically illustrates an example of a method of energizing a panel in the repair operation.

FIG. 16 schematically illustrates a subpixel layout according to a modification example 1-1.

FIG. 17 schematically illustrates layouts of the color filter layer, the organic layer (the light-emission layer), and the bank apertures that constitute the pixel layout illustrated in FIG. 16.

FIG. 18 is a schematic cross-sectional view illustrating an example of the tandem configuration of the organic layer illustrated in FIG. 17.

FIG. 19 schematically illustrates layouts of the color filter layer, the organic layer (the light-emission layer), and the bank apertures that constitute a pixel layout according to a modification example 1-2.

FIG. 20 is a schematic cross-sectional view illustrating an example configuration of separate forming of the organic layer illustrated in FIG. 19.

FIG. 21 schematically illustrates layouts of the color filter layer, the organic layer (the light-emission layer), and the bank apertures that constitute a pixel layout according to a modification example 1-3.

FIG. 22 is a schematic cross-sectional view illustrating an example configuration of separate forming of the organic layer illustrated in FIG. 21.

FIG. 23 schematically illustrates layouts of the color filter layer, the organic layer (the light-emission layer), and the bank apertures that constitute a pixel layout according to a modification example 1-4.

FIG. 24 is a schematic cross-sectional view illustrating an example configuration of separate forming of the organic layer illustrated in FIG. 23.

FIG. 25 is a cross-sectional view illustrating an element configuration including an anode reflector according to a modification example 2.

FIG. 26 is a plan view illustrating an example of a layout of the apertures illustrated in FIG. 25.

FIG. 27 is a cross-sectional view illustrating a configuration example of the aperture illustrated in FIG. 25.

FIG. 28 illustrates rays in the aperture illustrated in FIG. 25.

FIG. 29 is a plan view illustrating another example of a layout of the apertures illustrated in FIG. 25.

FIG. 30A is a plan view illustrating another example of the aperture illustrated in FIG. 25.

FIG. 30B is a plan view illustrating another example of the aperture illustrated in FIG. 25.

FIG. 30C is a plan view illustrating another example of the aperture illustrated in FIG. 25.

FIG. 30D is a plan view illustrating another example of the aperture illustrated in FIG. 25.

FIG. 30E is a plan view illustrating another example of the aperture illustrated in FIG. 25.

FIG. 31 is a plan view illustrating another example of the layout of the apertures illustrated in FIG. 25.

FIG. 32 is a plan view illustrating another example of the layout of the apertures illustrated in FIG. 25.

FIG. 33A is a plan view illustrating another example of the layout of the apertures illustrated in FIG. 25.

FIG. 33B is a plan view illustrating another example of the layout of the apertures illustrated in FIG. 25.

FIG. 34 is a plan view illustrating another example of the layout of the apertures illustrated in FIG. 25.

FIG. 35 is a plan view illustrating another example of the layout of the apertures illustrated in FIG. 25.

FIG. 36A is a plan view illustrating another example of the layout of the apertures illustrated in FIG. 25.

FIG. 36B is a plan view illustrating another example of the layout of the apertures illustrated in FIG. 25.

FIG. 36C is a plan view illustrating another example of the layout of the apertures illustrated in FIG. 25.

FIG. 36D is a plan view illustrating another example of the layout of the apertures illustrated in FIG. 25.

FIG. 37A is a plan view illustrating another example of the layout of the apertures illustrated in FIG. 25.

FIG. 37B is a plan view illustrating another example of the layout of the apertures illustrated in FIG. 25.

FIG. 37C is a plan view illustrating another example of the layout of the apertures illustrated in FIG. 25.

FIG. 37D is a plan view illustrating another example of the layout of the apertures illustrated in FIG. 25.

FIG. 37E is a plan view illustrating another example of the layout of the apertures illustrated in FIG. 25.

FIG. 37F is a plan view illustrating another example of the layout of the apertures illustrated in FIG. 25.

FIG. 38A is a plan view illustrating another example of the layout of the apertures illustrated in FIG. 25.

FIG. 38B is a plan view illustrating another example of the layout of the apertures illustrated in FIG. 25.

FIG. 39 is a plan view illustrating an overall configuration of a module including the display device illustrated in FIG. 1 and so on.

FIG. 40 is a perspective view illustrating a configuration of a television set.

FIG. 41A is a perspective view illustrating a configuration of a digital still camera.

FIG. 41B is a perspective view illustrating a configuration of a digital still camera.

FIG. 42 is a perspective view illustrating an appearance of a personal computer.

FIG. 43 is a perspective view illustrating an appearance of a video camera.

FIG. 44A is a plan view illustrating a configuration of a mobile phone.

FIG. 44B is a plan view illustrating a configuration of a mobile phone.

FIG. 45A is a perspective view illustrating a configuration of a smart phone.

FIG. 45B is a perspective view illustrating a configuration of a smart phone.

FIG. 46A schematically illustrates a manufacturing process of an organic EL element according to a comparative example.

FIG. 46B schematically illustrates the manufacturing process of the organic EL element according to the comparative example.

### DETAILED DESCRIPTION

In the following, some embodiments of the present disclosure will be described in detail with reference to the accompanying drawings. It is to be noted that description will be made in the following order.

1. Embodiment (one example of a display device that includes a two-layered second electrode, the second electrode including an insulated (high-resistance) portion in a local region on a light-emission layer side)
Configuration
Manufacturing method (including a repair process)

2. Modification Example 1-1 to 1-4 (other examples of a subpixel layout)

3. Modification Example 2 (one example of an anode reflector)

4. Application Example (examples of electronic apparatuses)

### Embodiment

### Configuration

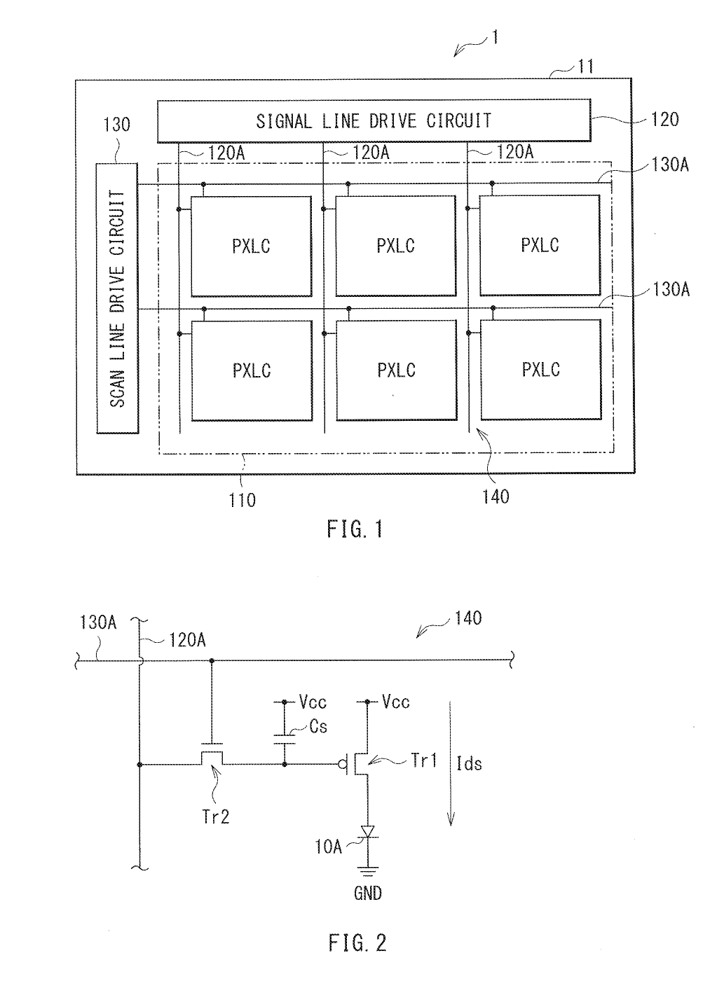

FIG. 1 illustrates a configuration of a display device (a display device 1) according to an embodiment of the present disclosure. The display device 1 is, for example, an organic EL display device, and includes a display region 110 on a substrate 11, in which a plurality of pixels (subpixels) PXLC are arrayed, for example, in a matrix. Each of the pixels PXLC includes an organic EL element 10A and is configured to produce, for example, red light LR (of a wavelength of 620 nm to 750 nm both inclusive), green light LG (of a wavelength of 495 nm to 570 nm both inclusive), blue light LB (of a wavelength of 450 nm to 495 nm both inclusive), or white light LW. Here, description is given on an example in which a unit of these four kinds of pixels PXLC (an R pixel, a G pixel, a B pixel, and a W pixel) constitutes one pixel. In a periphery of the display region 110, provided are a signal line drive circuit 120 and a scan line drive circuit 130.

In the display region 110, provided is, for example, an active matrix drive circuit (a pixel drive circuit 140). The pixel drive circuit 140 includes, as illustrated in FIG. 2, a transistor Tr1 for driving and a transistor Tr2 for writing, with a capacitor Cs provided between the transistors Tr1 and Tr2. Between a first power supply line (Vcc) and a second power supply line (GND), the organic EL element 10A is connected in series to the transistor Tr1. The signal line drive circuit 120 is configured to supply image signals to source electrodes of the transistors Tr2 through a plurality of signal lines 120A arranged in a column direction. The scan line drive circuit 130 is configured to supply, in order, scan signals to gate electrodes of the transistors Tr2 through a plurality of scan lines 130A arranged in a row direction.

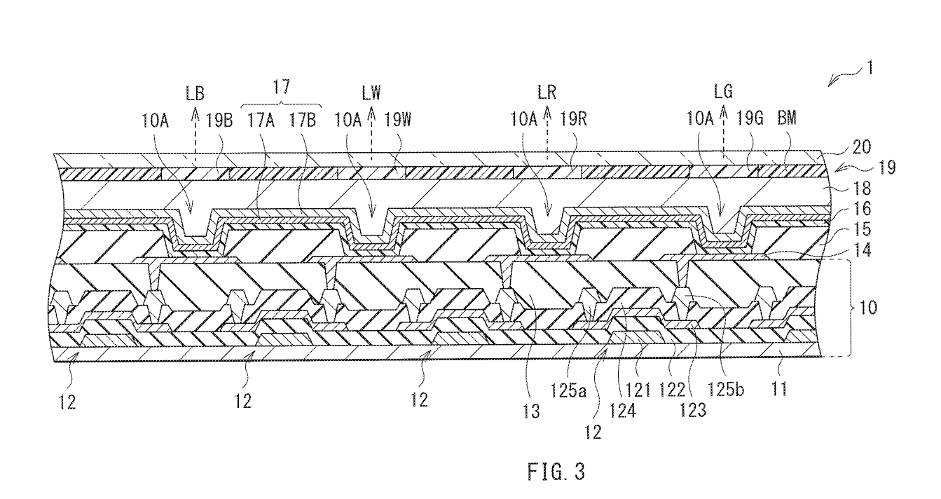

FIG. 3 illustrates in section a configuration of the display device illustrated in FIG. 1. It is to be noted that FIG. 3 illustrates a region corresponding to the pixels PXLC of the above-mentioned four colors. The display device 1 is an organic EL display device of a so-called top-emission type (an upper-surface-light-emission type), in which, for example, light produced in the organic EL element 10A is extracted upward of a sealing substrate 20. The organic EL element 10A has an element configuration in which white light is produced. White light produced in each of the organic EL elements 10A passes through a color filter layer 19 (color filters 19R, 19G, 19B, and 19W) to allow the above-mentioned light LR, LG, LB, and LW to be emitted.

The organic EL element 10A is provided between a driver substrate 10 and the sealing substrate 20. The driver substrate 10 is provided, on the substrate 11, with the pixel drive circuit 140 that is configured to drive each of the organic EL elements 10A (FIG. 3 illustrates a TFT 12 that serves as the above-mentioned transistor Tr1). A surface of the driver substrate 10 is covered with a planarization layer 13. On the planarization layer 13, provided is a first electrode 14 as, for example, an anode. The first electrode 14 is electrically connected to the TFT 12 provided on the driver substrate 10.

In the organic EL elements 10A, the first electrode 14, a bank (an inter-pixel insulating film) 15, an organic layer 16 including a light-emission layer, and a second electrode 17 as, for example, a cathode are laminated in the order from the driver substrate 10 side. Above the organic EL elements 10A, the sealing substrate 20 is bonded with a protective layer 18 in between. The sealing substrate 20 is provided with a color filter layer 19 that includes the color filters 19R, 19G, 19B, and 19W, and a black matrix layer BM. In the color filter layer 19, the black matrix layer BM is formed in a lattice shape, and the color filters 19R, 19G, 19B and 19W is formed in apertures in the lattice shape of the black matrix layer BM.

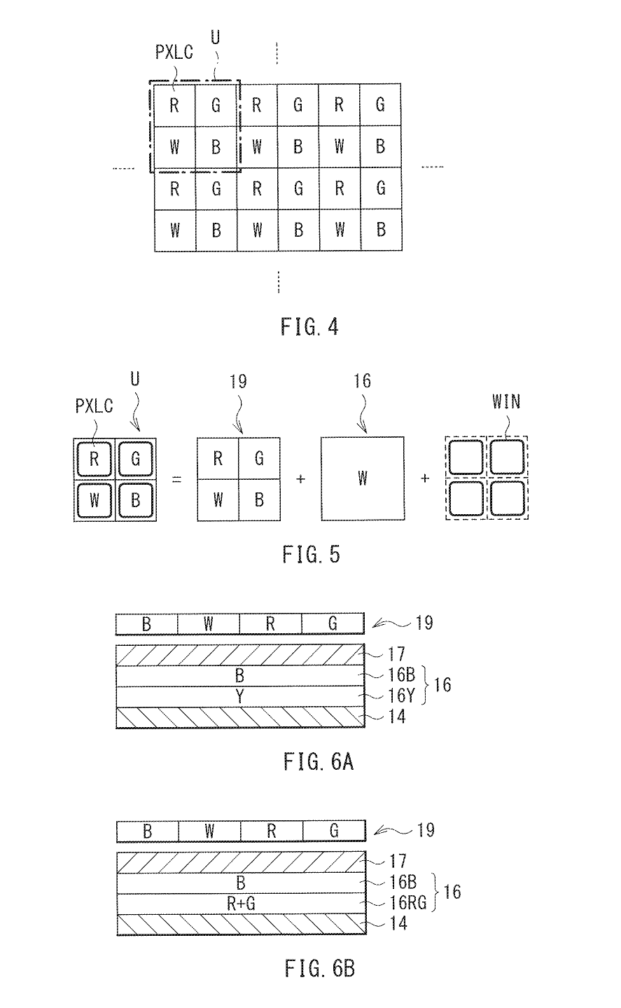

FIG. 4 illustrates an example of a layout of the pixels PXLC including the organic EL elements 10A. As illustrated, for example, the four pixels PXLC of R, G, B, and W are arranged in an array of two rows and two columns (in a shape of a crossed square), and the four pixels PXLC constitute a display unit U (one pixel).

FIG. 5 illustrates an example of layouts of the color filter layer 19, the organic layer 16 (specifically, the organic electroluminescent layer) and apertures WIN (apertures of the bank 15) that constitute the above-mentioned four pixels PXLC. As illustrated, in the example embodiment, a color arrangement (R, G, B, W) of the color filter layer 19 corresponds to a layout of the pixels PXLC, and the organic layer 16 includes a white light-emission layer (W) that is common to the four pixels PXLC. The apertures WIN of the bank 15 are provided in one-to-one correspondence with the pixels PXLC.

In the following, description is given on a configuration of each portion of the display device 1.

The substrate 11 is configured of, for example, glass, silicon (Si), a resin or a conductive substrate and so on. The conductive substrate may be used, for example, with its surface insulated by silicon oxide (SiO₂), a resin or the like.

The TFT 12 is a thin film transistor (TFT), for example, of a bottom gate type, and is configured of, for example, a metal oxide semiconductor field effect transistor (MOSFET). In the TFT 12, on the substrate 11, a gate electrode 121 that is patterned, for example, with an insulating film in between, a gate insulating film 122, a semiconductor thin film 123 (for example, polisilicon) that constitutes a channel, an interlayer insulating film 124 are laminated in the order. A source electrode 125a and a drain electrode 125b are formed on the respective end side of the semiconductor layer 123. To the drain electrode 125b, the first electrode 14 is electrically connected. It is to be noted that the transistor Tr1 is not limited to that of a bottom gate type, but may be that of a top gate type. The semiconductor thin film 123 may be configured of crystalline silicon or amorphous silicon, or may be configured of oxide semiconductor.

The planarization film 13 is provided for planarization of the surface of the driver substrate 10, and allows each layer of the organic EL element 10A to be formed with a uniform thickness. The planarization film 13 is provided with a contact hole that electrically connects the first electrode 14 and the drain electrode 125b of the TFT 12, and has a function of preventing them from coming into unintended contact. Examples of constituent materials of the planarization film 13 may include organic materials such as a polyimide resin, an acrylic resin, and a novolac resin, or inorganic materials such as silicon oxide (SiO₂), silicon nitride (SiNx) or silicon oxynitride (SiON).

The first electrode 14 is provided to be electrically insulated for each pixel, and has, for example, light-reflectivity. The first electrode 14 preferably has as high light-reflectivity as possible for improving light-emission efficiency. Since the first electrode 14 serves as an anode, a material with high hole-injection ability is preferable. Examples of constituent materials of the first electrode 14 may include a single substance or an alloy of metal elements such as chromium (Cr), gold (Au), platinum (Pt), nickel (Ni), copper (Cu), molybdenum (Mo), tungsten (W), titanium (Ti), tantalum (Ta), or silver (Ag) and so on. On a surface of the first electrode 14, a transparent conductive film such as an oxide of indium and tin (ITO) may be provided. A thickness of the first electrode 14 may be appropriately set so as to balance wiring resistance against light-reflectivity (surface roughness).

Other than the above-described materials, a single substance or an alloy of aluminum may be used. Aluminum has high light-reflectivity, but a hole injection barrier may be formed due to a low work function. However, aluminum may be used as the first electrode 14 by providing an appropriate hole injection layer. The first electrode 14 may be a single-layer film or a layered film of a single substance or an alloy of the above-mentioned metals.

The bank 15 is configured to electrically separate the first electrode 14 for each pixel, and ensure insulation between the first electrode 14 and the second electrode 17. The bank 15 has the apertures WIN in selective regions that each face the first electrode 14, and defines a light-emission region of each of the organic EL elements 10A. The bank 15 is configured of an insulating material such as, for example, silicon oxide, polyimide, or a photosensitive resin.

The organic layer 16 includes the light-emission layer (the organic electroluminescent layer). Here, the organic layer 16 is a white light-emission layer that is common to the organic EL elements 10A. The organic layer 16 may include, for example, a hole transport layer (HTL), a hole injection layer (HIL), and an electron transport layer (ETL) and so on, as well as the light-emission layer. An electron injection layer (EIL) such as LiF may be provided between the organic layer 16 and the second electrode 17.

Specifically, as illustrated in FIG. 6A, the organic layer 16 (the light-emission layer) includes, for example, a yellow light-emission layer 16Y and a blue light-emission layer 16B that are laminated in the order from the first electrode 14 side. The yellow light-emission layer 16Y includes a material that is configured to produce yellow (Y) light by recombination of paired electron-holes. The blue light-emission layer 16B includes a material that is configured to produce blue (B) light by recombination of paired electron-holes. The light of respective colors from the yellow light-emission layer 16Y and the blue light-emission layer 16B is color-mixed to allow white light as a whole to be emitted from the organic layer 16.

The lamination order of the yellow light-emission layer 16Y and the blue light-emission layer 16B in the organic layer 16 may be inverted from as described above. Specifically, the blue light-emission layer 16B may be disposed on the first electrode 14 side, and the yellow light-emission layer 16Y may be disposed on the second electrode 17 side. The constituent material of the yellow light-emission layer 16Y is not limited to a material that configured to produce yellow (Y) light as described above, but may be other materials. For example, as the yellow light-emission layer 16RG illustrated in FIG. 6B, the yellow light-emission layer 16Y may be configured of a material that is configured to produce red (R) light doped with a material that is configured to produce green (G) light. Also in this example, the lamination order of the yellow light-emission layer 16RG and the blue light-emission layer 16B may be inverted.

The second electrode 17 has light-transmittance, and for example, provided over an entire surface of the display region, commonly to the organic EL elements 10A. The second electrode 17 is configured of, for example, a transparent conductive film such as indium zinc oxide (IZO) or a translucent conductive film. Other examples of a constituent material of the transparent conductive film may include indium tin oxide (ITO), zinc oxide (ZnO), alumina-doped zinc oxide (AZO), gallium-oxide-doped zinc oxide (GZO), or indium titanium oxide (ITiO) and so on. The second electrode 17 may be formed, for example, by a sputtering method.

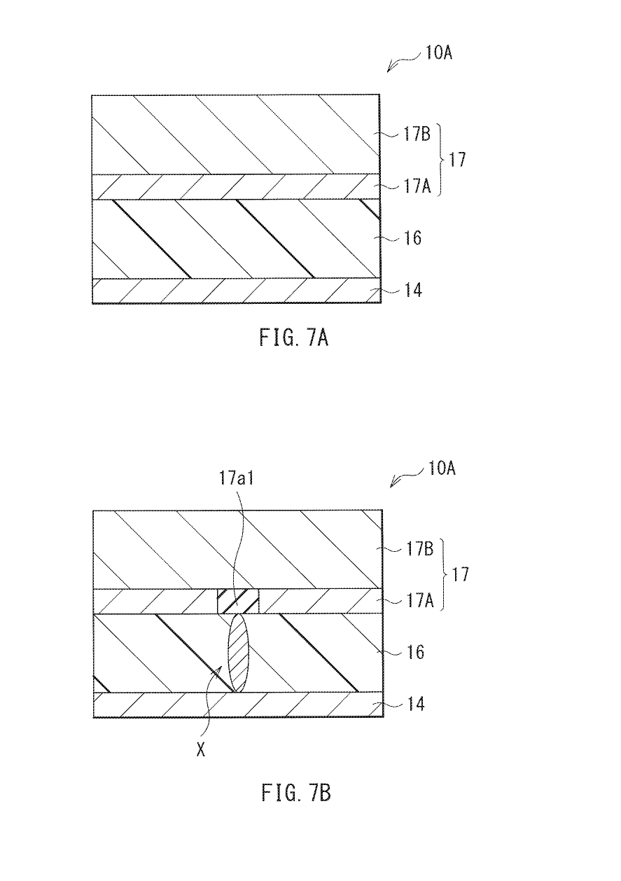

FIG. 7A illustrates, in an enlarged manner, an element configuration of the organic EL element 10A. In the example embodiment, the second electrode 17 has a multi-layered structure including the transparent conductive film as described above. Specifically, in the second electrode 17, a first conductive film 17A and a second conductive film 17B are laminated in the order from the organic layer 16 side. Among them, the first conductive layer 17A is formed before a repair process, which is to be described later. The second conductive layer 17B is formed after the repair process. For example, the first conductive layer 17A and the second conductive layer 17B are both configured of the transparent conductive films as described above. Here, the first conductive film 17A and the second conductive film 17B are configured of the same material (for example, IZO).

However, in the second electrode 17, the first conductive film 17A and the second conductive film 17B may be configured of different materials from each other. For example, the first conductive film 17A may include an alloy of magnesium and silver (Mg—Ag, magnesium-silver), and the second conductive film 17B may include a transparent conductive film such as IZO. Since Mg—Ag is allowed to be translucent by thinning, Mg—Ag is used in a case of utilizing an optical resonance phenomenon by a micro cavity, which is to be described later. Alternatively, one of the first conductive film 17A and the second conductive film 17B may be a transparent conductive film, and another may be a metal film. For example, in a case of adopting an element configuration of a bottom-emission type and so on, the first conductive film 17A may be a transparent conductive film, and the second conductive film 17B may be a reflective metal film similarly to the first electrode 14.

A thickness of the first conductive film 17A may be smaller than a thickness of the second conductive film 17B. Specifically, the first conductive film 17A may have a thickness (of, for example, a few nanometers to several tens of nanometers both inclusive) with which the first conductive film 17A is allowed to have sufficiently high resistance (or to be insulated) in the repair process (a dark spot eliminating process), which is to be described later. The second conductive layer 17B may have a thickness (of, for example, several tens of nanometers to several hundreds of nanometers both inclusive) with which the second conductive film 17B is allowed to have a desired resistance value. Thus, the first conductive film 17A may be a thin film having a thickness that is equal to or smaller than, for example, about one tenth of the thickness of the second conductive film 17B.

FIG. 7B illustrates, in an enlarged manner, an element configuration of the organic EL element 10A (in the vicinity of a foreign matter X). As illustrated, in a case that a foreign matter X intrudes into the organic layer 16, the second electrode 17 includes an insulated (high-resistance) portion 17a1 (a local portion) in a region corresponding to the foreign matter X. The insulated portion 17a1 is formed in the repair process, which is to be described later, and has a function of electrically disconnecting a short-circuited path between the first electrode 14 and the second electrode 17 due to the foreign matter X. The insulated portion 17a1 is provided in a scattered state, within a surface of, for example, the second electrode 17, at a plurality of spots corresponding to a plurality of foreign matters X. The insulated portion 17a1 is formed selectively in the first conductive layer 17A out of the first conductive layer 17A and the second conductive layer 17B.

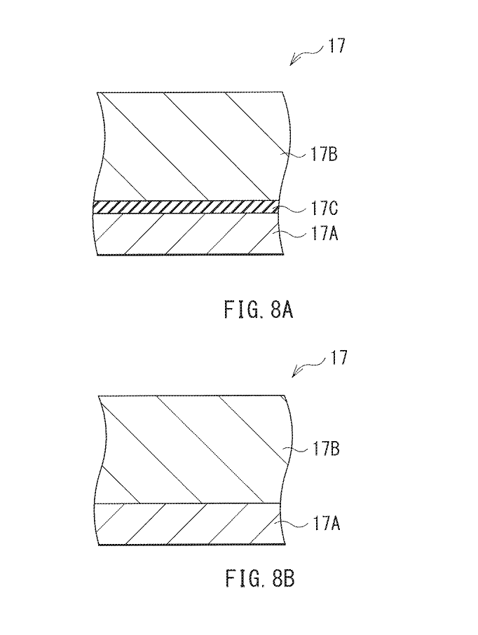

FIGS. 8A and 8B illustrate, in an enlarged manner, an interface in the second electrode 17. As illustrated in FIG. 8A, in the second electrode 17, an oxide film 17C may be formed between the first conductive film 17A and the second conductive film 17B. The oxide film 17C may be a thin film (a coating film) generated by oxidation of a surface of the first conductive film 17A, and may be generated along with formation of the above-mentioned insulated portion 17a1. To allow the electrical resistance of the oxide film 17C to be as low as possible, conditions in the repair process, which is to be described later, may be set appropriately.

Alternatively, as illustrated in FIG. 8B, the first conductive film 17A and the second conductive film 17B may be adjacently laminated (with the oxide film 17C removed). Thus, it is possible to eliminate resistance due to the oxide film 17C, which is advantageous in reducing the resistance of the second electrode 17.

The protective film 18 may be configured of, for example, silicon nitride, silicon oxide, a metal oxide, and so on. It is to be noted that an adhesive layer configured of, for example, a thermosetting resin or an ultraviolet curing resin may be provided between the protective film 18 and the sealing substrate 20.

The sealing substrate 20 is configured of a material (specifically, glass) that is transparent to light passing through the color filters 19R, 19G, 19B, and 19W. The color filter layer 19 may be provided either on a light-incident side (an element side) or on a light-exit side of the sealing substrate 20. For example, they are provided on the light-incident side. The color filters 19R, 19G, 19B, and 19W each are provided to face the organic EL element 10A. The color filters 19R, 19G, and 19B are configured to selectively allow red light, green light, and blue light to pass through. The color filter 19W is provided for obtaining, for example, a desired whiteness, and is a filter that adjusts chromaticity or luminance. It is to be noted that the color filter 19W may be omitted.

### [Manufacturing Method]

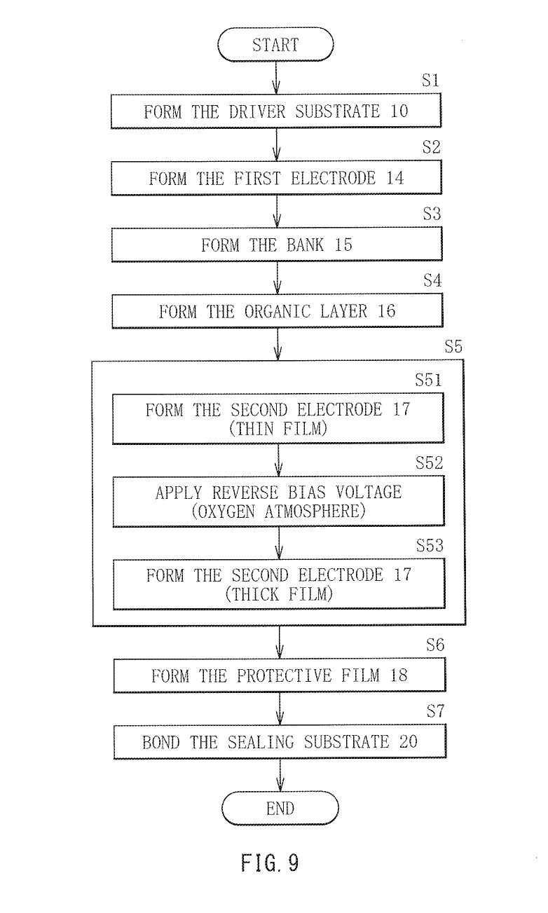

FIG. 9 illustrates a flow of a manufacturing process of the display device 1 as described above (a manufacturing process of the organic EL element 10A). As illustrated, first, the driver substrate 10 is formed (step S1). Specifically, on the substrate 11, by, for example, a low-temperature polisilicon process, the pixel drive circuit 140 is formed that includes the transistors Tr1 and Tr2, and the capacitor Cs and so on as described above. After this, the planarization film 13 is formed on an entire surface of the substrate 11, and then, the planarization film 13 is patterned to form contact holes and so on.

After this, on the planarization film 13 of the driver substrate 10, the first electrode 14 is formed (step S2). Specifically, for example, on the planarization film 13, the first electrode 14 configured of the above-mentioned material is formed by, for example, sputtering method, and then, the first electrode 14 is patterned by, for example, etching with the use of photolithography.

Subsequently, the bank 15 is formed (step S3). Specifically, the above-described insulating material is formed and then patterned to form the apertures WIN in the regions that each face the first electrode 14.

After this, the organic layer 16 is formed (step S4). Specifically, the white light-emission layer configured of the above-mentioned materials or the like is formed by, for example, a vacuum evaporation method. At this time, the hole injection layer, the hole transport layer, and the electron transport layer may be continuously formed by a vacuum consistent process.

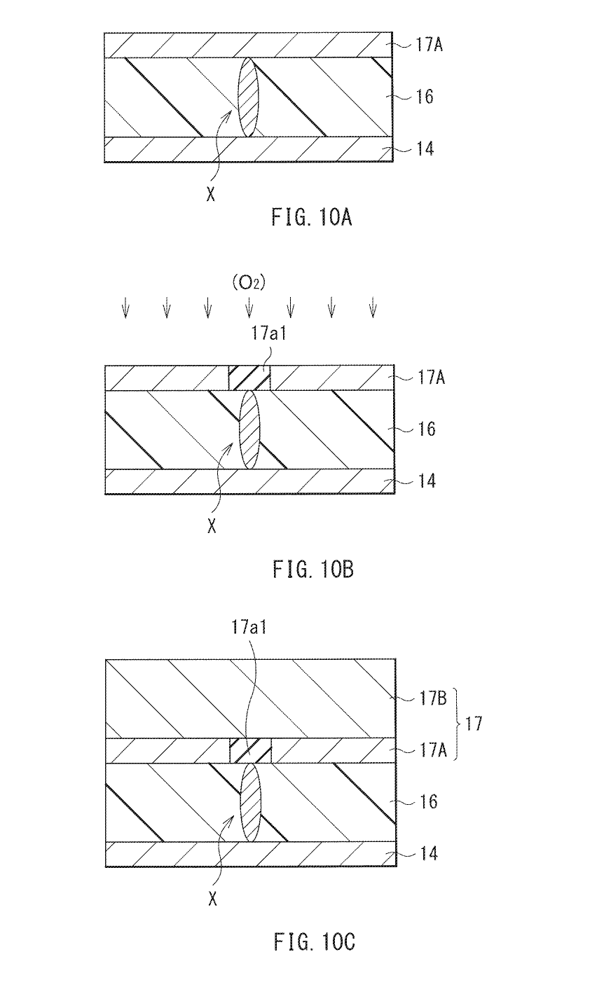

Next, the second electrode 17 is formed (step S5). Specifically, first, as illustrated in FIG. 10A, the first conductive film 17A configured of the above-mentioned materials or the like is formed by, for example, a sputtering method or the like (step S51). After this, as illustrated in FIG. 10B, a reverse bias voltage is applied (step S52) between the first conductive film 17A thus formed and the first electrode 14 in a predetermined oxygen atmosphere. Thus, a short-circuited path due to the foreign matter is electrically disconnected to remove (to repair) a portion that is to become a dark spot (a dark spot pixel). Subsequently, as illustrated in FIG. 10C, the second conductive film 17B configured of the above-mentioned materials or the like is formed by, for example, a sputtering method or the like (step S53). It is to be noted that, in the process of forming the second electrode 17, the repair process (step S52) is to be described later.

Subsequently, on the second electrode 17, the protective film 18 is formed (step S6) by, for example, a chemical vapor deposition (CVD) method. Finally, the sealing substrate 20 on which the color filter layer 19 is formed is bonded (step S7). Thus, the display device 1 as illustrated in FIG. 3 is completed.

### [Repair Process]

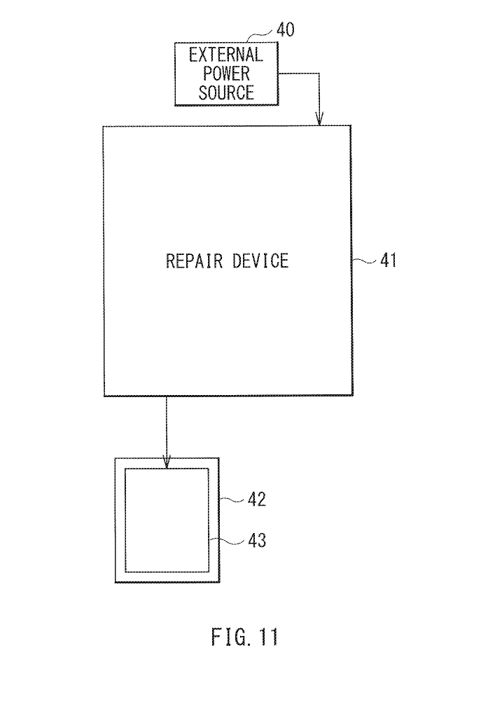

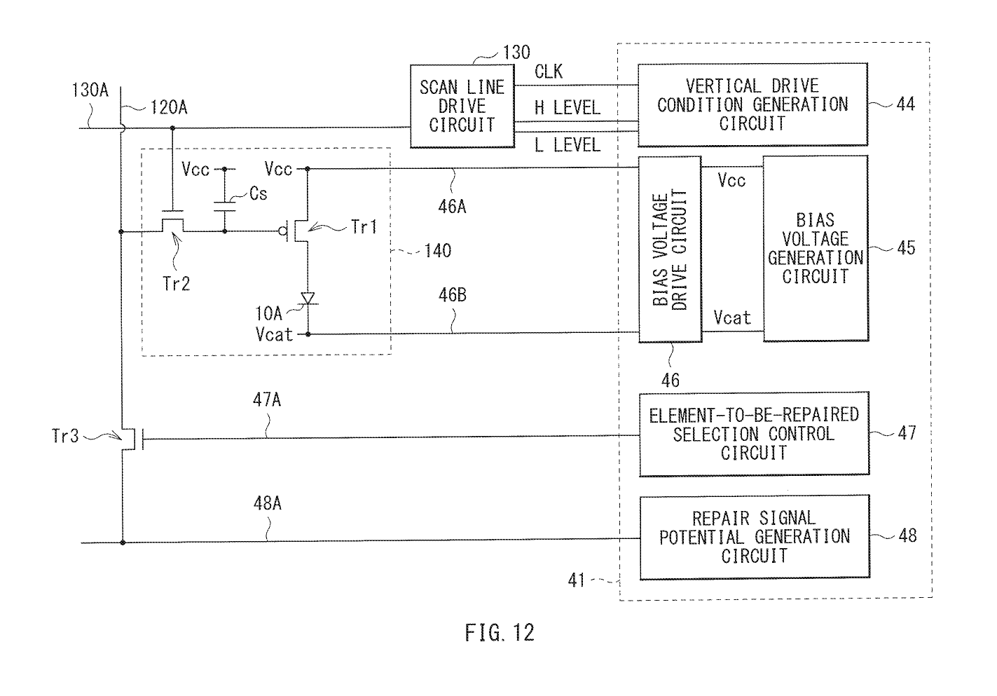

FIG. 11 illustrates a system configuration including a repair device (a repair device 41) used in the process of applying the reverse bias voltage. The repair device 41 is connected to an external power source 40, and is configured to energize a panel 43 mounted in a mounting section 42 based on power supplied from the external power source 40. The mounting section 42 is provided for placing the panel 43 on a predetermined place, and may include, for example, a hotplate and so on. Here, the panel 43 as an object-to-be-repaired is in a semi-finished product state in the manufacturing process. Specifically, the panel 43 is an element substrate in a state that the first electrode 14, the bank 15, the organic layer 16, and the first conductive film 17A are formed on the driver substrate 10 on which the pixel drive circuit 140, the scan line drive circuit 130, and the signal line drive circuit 120 are formed (in a state before a signal line driver IC and so on are connected). FIG. 12 illustrates a functional configuration of the repair device 41 together with a configuration of the pixel drive circuit 140 and the scan line drive circuit 130.

### (1 Configuration of Repair Device)

The repair device 41 may include, for example, a vertical drive condition generation circuit 44, a bias voltage generation circuit 45, a bias voltage drive circuit 46, an element-to-be-repaired selection control circuit 47, and a repair signal potential generation circuit 48. The repair device 41 is, for example, configured to perform a repair operation of a dark spot by supplying a repair signal to the pixel drive circuit 140 in a specific region, with the signal line drive circuit 120 in the panel 43 (the display device 1) suspended, and by applying the reverse bias voltage to the organic EL element 10A.

The vertical drive condition generation circuit 44 is configured to generate two kinds of selection signal potentials (H level and L level) that satisfy drive conditions desired in the repair, and a clock signal. The selection signal potential (H level) is a signal potential (a high level) used to control the pixel drive circuit 140 in a selected state, and may be, for example, 17 V. The selection signal potential (L level) is a signal potential (a low level) used to control the pixel drive circuit 140 in a non-selected state, and may be, for example, −3 V. The two kinds of selection signal potentials are configured to be applied to the scan lines 130A through the scan line drive circuit 130. The clock signal is configured to be generated for scanning operation of the scan line drive circuit 130. The clock signal may be similar to that used in a normal display operation. It is to be noted that a clock signal dedicated to the repair operation may be generated to control a specific selected line in a selected state for a long time.

The bias voltage generation circuit 45 is configured to generate a power supply voltage Vcc and a cathode line voltage Vcat. The power supply voltage Vcc is configured to be supplied to the anode side of the organic EL element 10A through a power supply line 46A. The cathode line voltage Vcat is configured to be supplied to the cathode side of the organic EL element 10A through a cathode voltage supply line 46B. Thus, in the repair operation, the reverse bias voltage (where Vcc is smaller than Vcat (Vcc<Vcat)) is applied to the organic EL element 10A, while, in a display operation, a forward bias voltage (where Vcc is larger than Vcat (Vcc>Vcat)) is applied to the organic EL element 10A.

As an example, a potential of, for example, 5 V is generated as the power supply voltage Vcc, while two kinds of potentials of, for example, 0 V and 10 V are generated as the cathode line voltage Vcat. The two kinds of potentials are provided for alternate application of the reverse bias voltage (in the repair operation) and the forward bias voltage (in the display operation). However, the voltage applied is not limited to an alternative voltage, but may be a direct voltage. For example, in a case of direct application of the reverse bias voltage, for example 10 V may be generated as the cathode line voltage Vcat. By applying 5 V to the power supply line 46A while applying 10 V to the cathode voltage supply line 46B, the reverse bias voltage of 5 V is applied to the organic EL element 10A.

The bias voltage drive circuit 46 is configured to alternately apply, for example, 0 V and 10 V to the cathode voltage supply line 46B. In other words, the bias voltage drive circuit 46 is configured to alternately apply the forward bias voltage and the reverse bias voltage to the organic EL element 10A. Alternately driving the cathode line voltage Vcat is for charging a capacitor component parasitic on the organic EL element 10A to allow a current to easily flow into a short-circuit that causes a dark point.

The element-to-be-repaired selection control circuit 47 is used to control turning on or off a select transistor Tr3. In other words, the element-to-be-repaired selection control circuit 47 is used for application of the reverse bias voltage to a selective pixel or selective pixels. As to a control signal here, there may be generated as many control signals as the element-to-be-repaired selection lines 47A.

The element-to-be-repaired selection control circuit 47 is configured, in the repair operation, to turn on the select transistor Tr3 of the signal line 120A regarding the element-to-be-repaired (to turn the select transistor Tr3 into a closed state), allowing the signal line 120A to be connected to a signal line for repair 48A. On the other hand, in the display operation, the element-to-be-repaired selection control circuit 47 is configured to turn off all the select transistors Tr3 (to turn all the select transistors Tr3 into an opened state), allowing the signal line 120A and the signal line for repair 48A to be in a disconnected state.

It is to be noted that the element-to-be-repaired selection line 47A may be arranged in one-to-one correspondence with the signal line 120A. Alternatively, one element-to-be-repaired selection line 47A may be arranged for a plurality of signal lines 120A. For example, an effective display region may be divided in two, i.e. the right region and the left region, and two element-to-be-repaired selection lines 47A may be arranged to correspond to the respective regions thus divided. Further, for example, with a plurality of subpixels that constitute one pixel considered as a unit, the element-to-be-repaired selection line 47A may be arranged for each unit. In these cases, it is possible to perform the repair in region unit or in pixel unit. That is, by appropriately setting a combination of the element-to-be-repaired selection control circuit 47, the element-to-be-repaired selection line 47A, and the select transistor Tr3, it is possible to apply a potential that satisfies a repair condition to a specific region.

The repair signal potential generation circuit 48 is configured to generate a signal potential for repair that is applied to the signal line 120A selected by the element-to-be-repaired selection control circuit 47 and the select transistor Tr3. For example, 17 V is generated as black level (for non-repair), and 0 V is generated as white level (for repair). As to a signal potential here, there may be generated as many signal potentials as the signal lines for repair 48A. In this connection, in the display operation, the signal line 120A is supplied with a potential of, for example, 5 V as black level and 1.5 V as white level.

It is to be noted that the signal line for repair 48A may be arranged in one-to-one correspondence with the signal line 120A. Alternatively, one signal line for repair 48A may be arranged for a plurality of signal lines 120A. For example, with a plurality of subpixels that constitute one pixel considered as a unit, the signal line for repair 48A may be arranged for each unit. Further, for example, the signal line for repair 48A may be arranged for each color pixel, i.e. R, G, B, and W. In other words, the signal line for repair 48A may be arranged for each color, commonly to the pixels in the same color.

A signal potential applied to the signal line for repair 48A may be, for example, a direct voltage. In a case of application of a direct voltage, it is possible to apply a constant repair signal (voltage) to the whole display. Alternatively, the signal potential applied to the signal line for repair 48A may be, for example, a pulsed repair signal (voltage) that is synchronized with the scan line drive circuit 130. In this case, it is possible to apply a constant repair signal (voltage) to a specific scan line (one selected line).

It is to be noted that the repair device 41 may be also used for inspection of a portion-to-be-repaired. In this case, the repair device 41 is configured to generate a potential for the display operation. For example, the vertical drive condition generation circuit 44 generates, for example, 7 V as a high potential and −8 V as a low potential. The bias voltage generation circuit 45 generates fixedly, for example, 5 V as the power supply voltage Vcc and −8 V as the cathode line voltage Vcat.

Thus, by performing inspection by the display operation using the repair device 41 to identify a portion of a dark spot or a dark spot pixel, it is possible to allow a specific region to be repaired. In this way, it is possible to allow the reverse bias voltage not to be applied to a portion or a pixel without the foreign matter (a portion that is not to become a dark spot). This enables effective repair operation. Also, it is possible to reduce damage to the organic layer 16 due to unnecessary application of the reverse bias voltage.

### (2 Repair Operation)

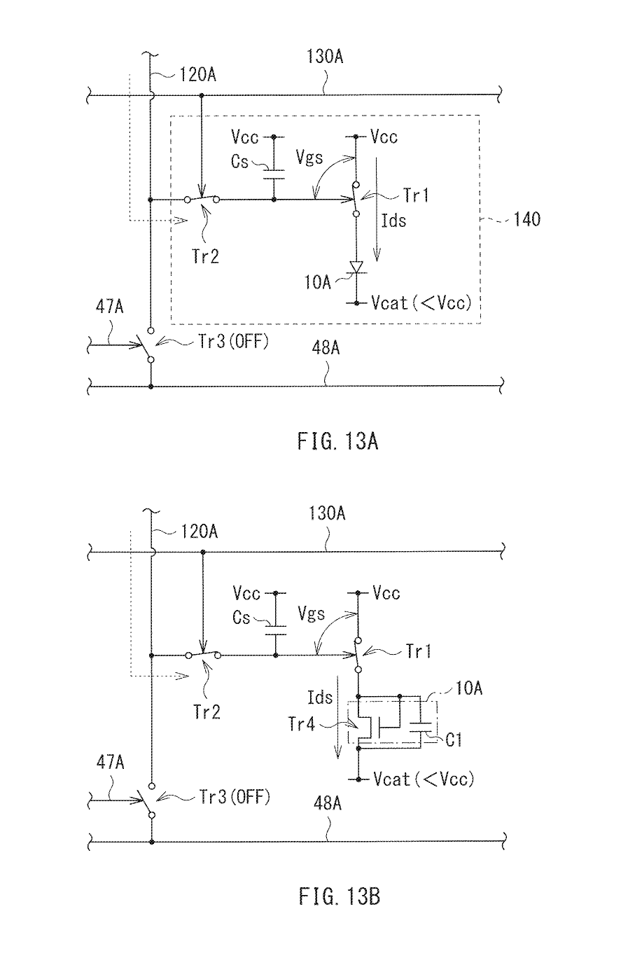

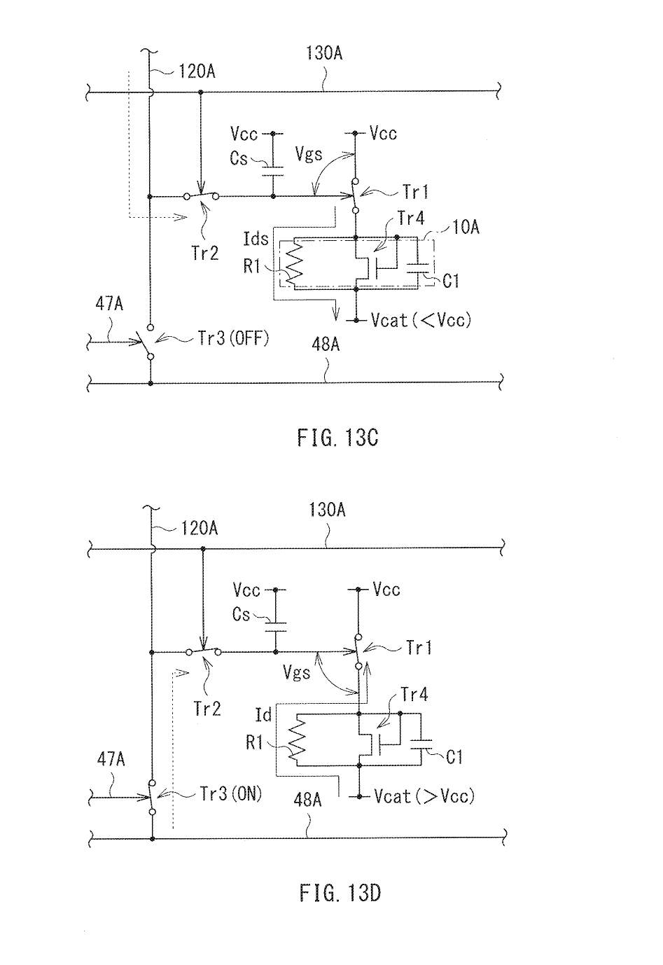

Prior to the repair operation, description is given on a case that the organic EL element 10A is allowed to emit light (the display operation of the organic EL element 10A). FIG. 13A illustrates an operation state of the pixel drive circuit 140 in the display operation, together with the element-to-be-repaired selection line 47A, the select transistor Tr3, and the signal line for repair 48A. FIG. 13B illustrates an operation state in a case of the normal light-emission in the display operation. It is to be noted that the transistors Tr1 to Tr3 are denoted by a circuit symbol for a switch, for indicating an ON/OFF state (an opened/closed state). In the display operation, in the pixel drive circuit 140, by the scan line drive circuit 130, an ON voltage is applied to the scan line 130A, and the transistor Tr2 is controlled into an ON state. Thus, signal data that is supplied from the signal line drive circuit 120 through the signal line 120A is applied to a gate of the transistor Tr1. At this time, the signal data is stored in the storage capacitor Cs. The signal data is stored even after the transistor Tr2 is switched to an OFF state. As a result, a drain current Ids corresponding to a gate-source voltage Vgs is allowed to continuously flow through the transistor Tr1. The drain current Ids is supplied to the organic EL element 10A, allowing the organic EL element 10A to continuously emit light.

In the display operation, the power supply voltage Vcc is, for example, 5 V, and the cathode line voltage Vcat is, for example, −8 V (Vcat is smaller than Vcc (Vcat<Vcc)). In other words, the forward bias voltage is applied to the organic EL element 10A. In the normal light-emission, as illustrated in FIG. 13B, the organic EL element 10A may be denoted by a diode-connected transistor Tr4 and a parasitic capacitor component C1.

By the way, in actuality, some of the organic EL elements 10A do not emit light normally due to the intrusion of the foreign matter or the like. FIG. 13C illustrates an example of an equivalent circuit in a case that the organic EL element 10A does not emit light normally. In this case, the organic EL element 10A may be denoted by the diode-connected transistor Tr4, the parasitic capacitor component C1, and a resistor component R1.

In a case like this, the drain current Ids flows through the resistor component R1, and does not flow (or rarely flows) through the transistor Tr4. Consequently, the organic layer 16 is not supplied with the drain current Ids, suppressing an organic electroluminescent phenomenon. This is a principle of occurrence of a dark spot (a dark spot pixel). The repair operation of such a dark spot may be carried out, for example, as follows.

### (Repair Operation by Alternative Reverse Bias Drive)

FIG. 13D illustrates an operation state of the pixel drive circuit 140 in the repair operation, together with the element-to-be-repaired selection line 47A, the select transistor Tr3, and the signal line for repair 48A. The organic EL element 10A is denoted by the diode-connected transistor Tr4, the parasitic capacitor component C1, and the resistor component R1. In this equivalent circuit, application of the reverse bias voltage to the organic EL element 10A allows a reverse current Id to flow through the resistor component R1 by a diode characteristic of the organic EL element 10A.

At this time, in the pixel drive circuit 140, the ON voltage is applied to the scan line 130A by the scan line drive circuit 130, and the transistor Tr2 is controlled into the ON state. On the other hand, the select transistor Tr3 is controlled into an ON state based on a signal supplied through the element-to-be-repaired selection line 47A. In the meanwhile, a low potential (for example, 0 V) is applied, through the signal line for repair 48A, to the signal line 120A that is connected to the pixel drive circuit 140 in a region (or a pixel) to be repaired. A high potential (for example, 17 V) is applied to the other signal lines 120A. Consequently, the transistor Tr1 in the region to be repaired is turned to the ON state. Thus, a bias voltage based on the cathode line voltage Vcat and the power supply voltage Vcc is applied to the organic EL element 10A connected to the drain of the transistor Tr1.

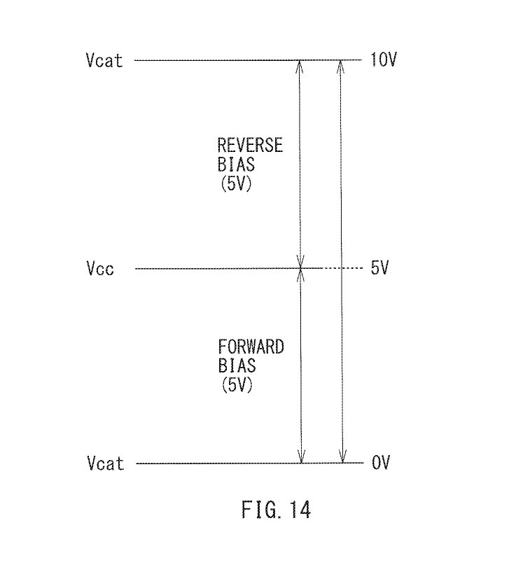

FIG. 14 illustrates an example of a drive condition of the bias voltage. As illustrated, the power supply voltage Vcc is fixed to, for example, 5 V, while the cathode line voltage Vcat is alternately switched between, for example, 0 V and 10 V. In this way, when 0 V is applied for the cathode line voltage Vcat, the forward bias voltage of 5 V is applied to the organic EL element 10A. On the other hand, when 10 V is applied for the cathode line voltage Vcat, the reverse bias voltage of 5 V is applied to the organic EL element 10A. The value of the bias voltage is set in consideration of pressure resistance of the organic layer 16 including the light-emission layer, and so on. It is to be noted that, in the example here, a thickness of the light-emission layer is assumed to be about 100 to 200 nm both inclusive.

In applying the reverse bias voltage, it is desirable that conditions such as an application time duration (a repair time duration) and a temperature are appropriately set. Specifically, a condition is set so as to allow the reverse current Id flowing through the resistor component R1 to become maximized, according to the parasitic capacitor component C1, a value of the current Id, and a magnitude of the bias voltage, and so on. For example, a drive frequency of the cathode line voltage Vcat is set to, for example, 100 to 600 Hz both inclusive, preferably, 300 to 400 Hz both inclusive. The application time duration is preferably as short as possible, for example, 5 to 30 minutes both inclusive. The temperature condition may be desirably set to, for example, 35 to 75° C. using, for example, a hotplate or the like. In particular, in the example embodiment, as illustrated in FIG. 10B, since a local region facing the foreign matter X is insulated (is made to have high resistance) by oxidation, it is desirable that the above-described reverse bias voltage drive is carried out in an oxygen atmosphere. Here, an oxygen concentration is desirably set to a condition that allows the insulated portion 17a1 to be formed and allows oxidation of a surface of the first conductive film 17A (the presence of the oxide film 17C as illustrated in FIG. 8A) to be within an allowable range. However, this does not apply to a case that the oxide film 17C is removed (as illustrated in FIG. 8B).

As described above, by applying the reverse bias voltage under appropriate conditions, a large current flows through the resistor component R1 (the short-circuited path or the short circuit due to the foreign matter X), causing an increase in temperature. As a result, in the first conductive film 17A, a portion that is in contact with the foreign matter X is locally overheated to be insulated by oxidation (to form the insulated portion 17a1). Thus, the short-circuited path due to the foreign matter X is electrically disconnected to eliminate a dark spot. In other words, in applying the forward bias voltage, a leak current to the resistor component R1 decreases (the drain current Ids supplied to the organic EL element 10A increases) to repair the organic EL element 10A into a normal state.

As described above, in the example embodiment, a dark spot is repaired internally by way of a current or a temperature without an external repair by, for example, laser irradiation. Moreover, even in a case that part or all of the scan line drive circuit 130 and the signal line drive circuit 120 are formed on the same substrate as the organic EL element 10A, it is possible to apply the reverse bias voltage to a specific region. Hence, it is possible to eliminate a dark spot effectively.

Here, depending on a magnitude of the parasitic capacitor component C1 that occurs in the organic EL element 10A, it may be difficult, in some cases, to allow the reverse current Id to flow through the resistor component R1 effectively. The alternative drive of the reverse bias voltage allows the parasitic capacitor component C1 to be charged, facilitating a current flow through the resistor R1. Moreover, the alternative drive allows excitons to be activated to repair the portion of a dark spot. This enables more effective repair.

Also, by performing the alternative reverse bias drive in a heated state, local oxidation in the first conductive film 17A is enhanced, leading to an increased efficiency of repair. Application of temperature makes it possible to restrain kinetic energy of a molecule and to relieve a load on the organic layer 16 due to the reverse bias voltage. This allows concentrated repair of a dark spot, while reducing damage to other normal regions.

When the organic EL element 10A goes into a normal state (where the insulated portion 17a1 is formed to eliminate a dark spot), in the above-described alternative drive, the cathode line voltage Vcat becomes, for example, 0 V to allow the forward bias voltage of 5 V to be applied to the organic EL element 10A. That is, the pixel drive circuit 140 becomes equivalent to FIG. 13B, allowing the drain current Ids to be supplied to the organic EL element 10A. Consequently, in the above-described repair operation, the portion (the pixel) that had been a dark spot begins to emit light, which enables confirmation that the repair has been completed.

### (Repair Operation by Direct Reverse Bias Drive)

The reverse bias voltage applied to the organic EL element 10A in the repair operation is not limited to alternative voltage as described above, but may be direct voltage. In this case, for example, 10 V is applied as the cathode line voltage Vcat, while 5 V is applied as the power supply voltage Vcc. Thus, the reverse bias voltage (of 5 V) is continuously applied to the organic EL element 10A. Also in the case of direct drive, by allowing the reverse current Id to flow continuously through the resistor component R1, it is possible to increase a temperature in the vicinity of the foreign matter X and to form the insulated portion 17a1 in the first conductive film 17A.

### (3 Panel Energization Method in Repair Operation)

In the repair operation as described above, as illustrated in FIG. 11, the panel 43 is mounted on the mounting section 42, and the panel 43 is energized (the reverse bias voltage is applied). At this time, the panel 43 is electrically connected to the repair device 41, specifically, by allowing a needle (a probe) (needles 50a to 50e) to touch (to be in contact with) a pad (pads 49a to 49e) formed in a periphery of the panel 43.

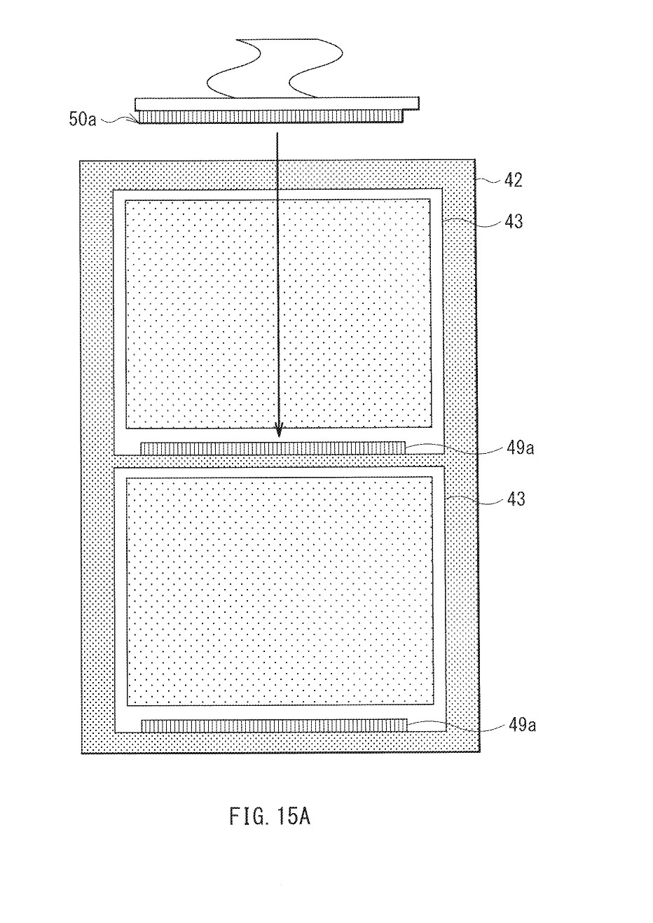

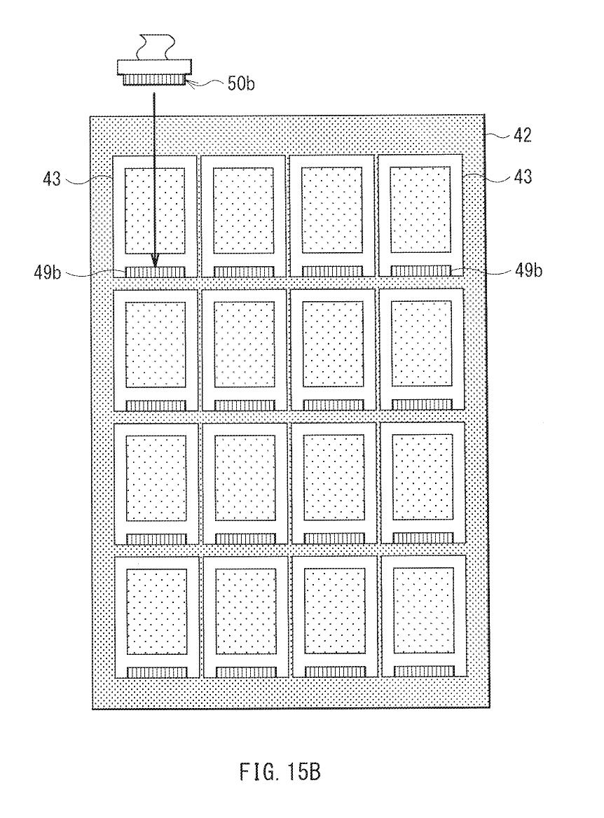

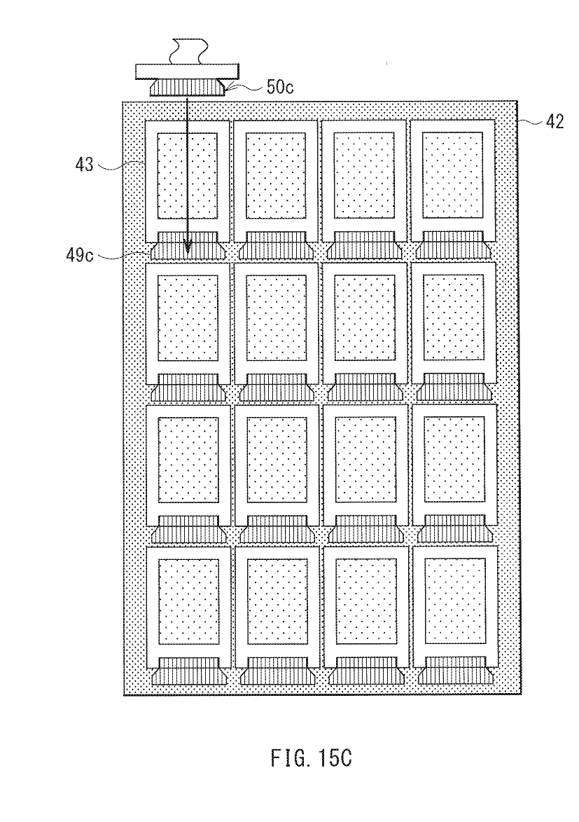

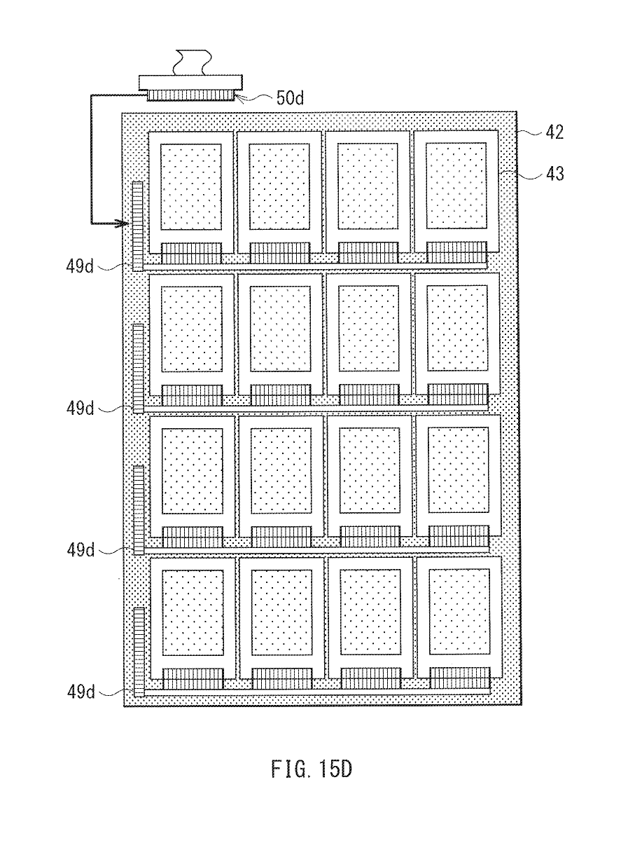

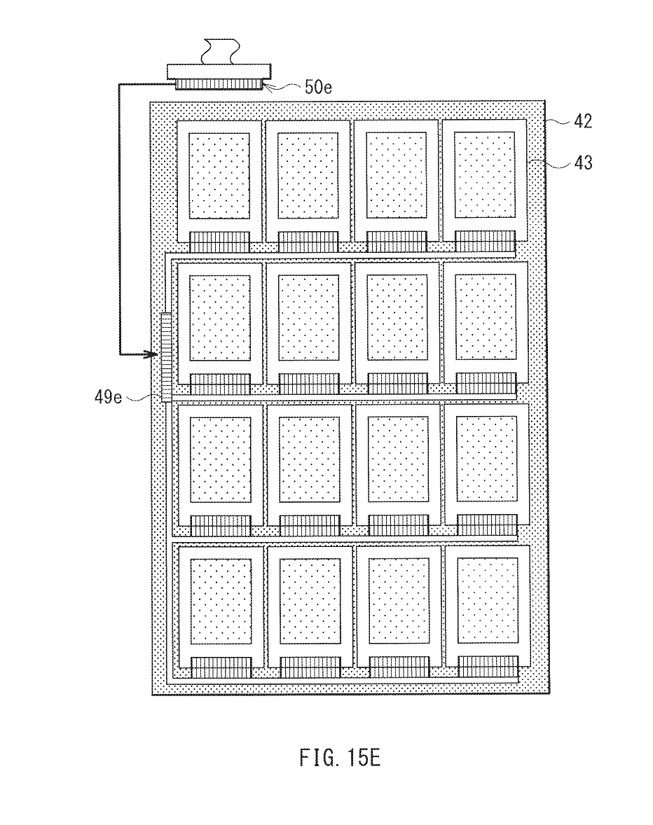

FIGS. 15A to 15E illustrate examples of energization methods. FIG. 15A illustrates a case that two panels 43 are formed on one glass substrate. The pad 49a provided on the panel 43 has the same width as that of the needle 50a. In energization, the needle 50a is allowed to touch the panel 43 (the pad 49a) in turn in one-to-one correspondence. FIG. 15B illustrates a case that even more (here, sixteen) panels 43 are formed on one glass substrate (a case of so-called multiple arrangement). The pad 49b provided on the panel 43 has the same width as that of the needle 50b. In energization, the needle 50b is allowed to touch the panel 43 (the pad 49b) in turn in one-to-one correspondence.

In FIG. 15C, in a case of, for example, multiple arrangement, a width of the pad 49c is larger than that of the pad 49b as illustrated in FIG. 15B. The width of the pad 49c is equal to a width of the needle 50c. In energization, the needle 50c is allowed to touch the panel 43 (the pad 49c) in turn in one-to-one correspondence. Since the pad width is larger, it is possible to allow accuracy in alignment with the needle 50c to be more relaxed than in an example of FIG. 15B.

In FIG. 15D, in a case of, for example, multiple arrangement, individual pads of the panel 43 are electrically connected along, for example, a row direction (or a column direction) to form, for each row, the pad 49d common to a plurality of panels 43. A width of the pad 49d is equal to a width of the needle 50d. In energization, the needle 50d is allowed to touch the pad 49d in turn, allowing a plurality of panels 43 to be energized in a batch. This leads to relaxing alignment accuracy as well as shortening a tact time. Alternatively, as illustrated in FIG. 15E, the pad 49e may be formed commonly to all the panels 43, which is more advantageous in relaxing alignment accuracy as well as shortening a tact time.

### [Operations and Effects]

In the display device 1 according to the example embodiment, as illustrated in FIGS. 1 and 2, a scan signal is supplied from the scan line drive circuit 130 to the gate of the transistor Tr2 of each pixel. In the meanwhile, an image signal is supplied from the signal line drive circuit 120 through the transistor Tr2 to the storage capacitor Cs and is stored in the storage capacitor Cs. In response to the signal stored in the storage capacitor Cs, the transistor Tr1 is controlled to turn on or off. Thus, a drive current (the drain current Ids) is injected into the organic EL element 10A. The drive current is injected into the light-emission layer in the organic layer 16 through the first electrode 14 and the second electrode 17. In the organic layer 16, light-emission occurs due to recombination of holes and electrons. Here, white light is produced from the organic layer 16 of each of the organic EL elements 10A.

When white light is produced from each of the organic EL elements 10A, the white light passes through the second electrode 17, the color filter layer 19 (any one of 19R, 19G, 19B, and 19W), and the sealing substrate 20 to be emitted upwardly of the display device 1. In this way, image display is performed with a unit of the organic EL elements 10A that produces color light of R, G, B, and W as one pixel.

Here, in the example embodiment, the second electrode 17 includes the first conductive film 17A and the second conductive film 17B that are laminated in order from the organic layer 16 side. This facilitates disconnecting electrically the short-circuited path that is formed between the first electrode 14 and the second electrode 17 (specifically, the first conductive film 17A) due to the foreign matter X in the manufacturing process.

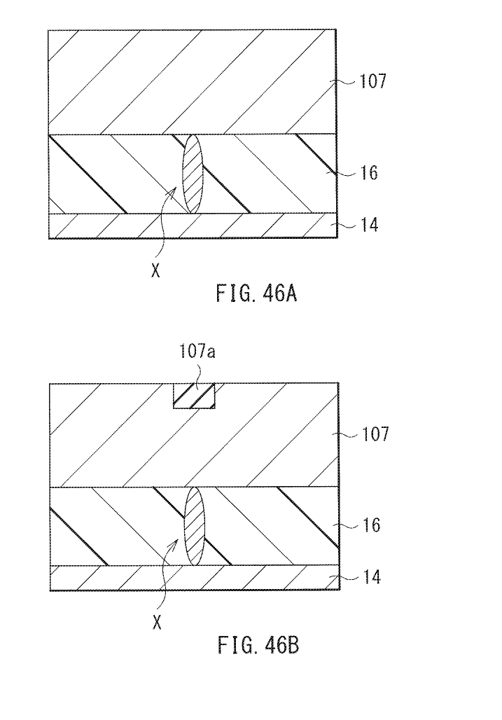

If, as illustrated in FIG. 46A, a second electrode 107 is configured of a single layer of a transparent conductive film, it is desirable that the second electrode 107 is thickened for lowered resistance. However, when the second electrode 107 is thickened, as illustrated in FIG. 46B, a spread of oxidation is limited to part (107a) of a surface of the second electrode 107, leading to a difficulty in insulating sufficiently a portion of a short circuit due to the foreign matter X.

On the other hand, in the example embodiment, since the second electrode 17 is two-layered, the first conductive film 17A is thinned. It is therefore possible to allow the first conductive film 17A to be insulated entirely in a thickness direction by applying the reverse bias voltage (as illustrated in FIG. 10B). Thus, it is possible to reduce an electrical influence such as a dark spot caused by the foreign matter X. After a process of forming the first conductive film 17A and the repair process, the second conductive film 17B is formed. The thickness of the second conductive film 17B may be set according to a desired resistance value. For example, in a case of an element configuration in which light-emission layers of different colors from one another are laminated to obtain white light, a transparent conductive film such as IZO is used for the second electrode 17. It is desirable that such a transparent conductive film have a thickness in a certain extent for lowered resistance. Hence, it is possible to thicken the second conductive film 17B, obtaining a desired resistance value (to reduce a resistance value). Thus, the second electrode 17 having a two-layered structure enables reduction in resistance of the second electrode 17, as well as elimination of a dark spot due to the foreign matter. This contributes to improvement in display quality.

In the following, description will be given on modification examples of the above-described example embodiment. It is to be noted that the similar components to the above-described example embodiment are denoted by the same references, and description thereof will be appropriately omitted.

### Modification Example 1-1

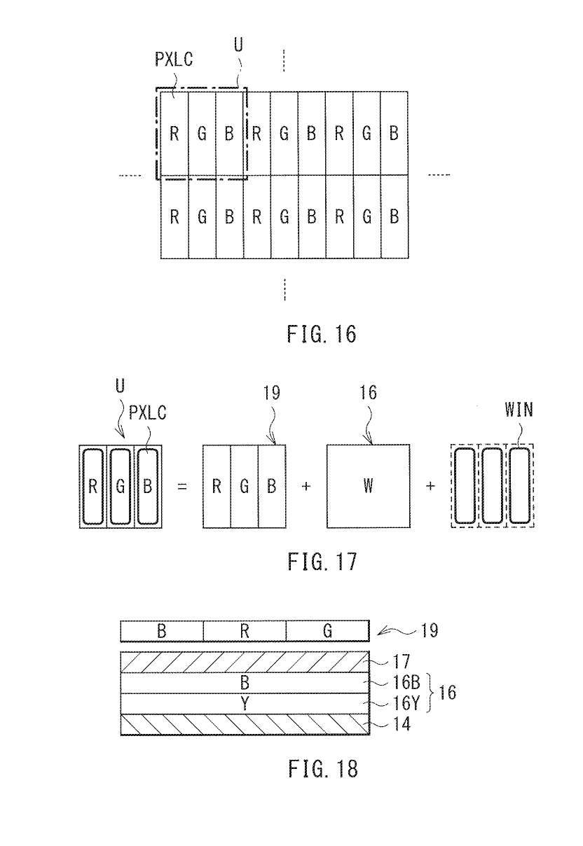

FIG. 16 illustrates an example of layout of the pixels PXLC according to a modification example 1-1. In the above-described example embodiment, description is given on a case that, for example, the four pixels PXLC of R, G, B, and W constitute the display unit U (a pixel). However, as in this modification example, the three pixels PXLC of R, G, B may constitute the display unit U. In this case of layout, the pixels PXLC in a strip shape are arranged in parallel in a stripe shape as a whole.

FIG. 17 illustrates an example of layouts of the color filter layer 19, the organic layer 16 (specifically, the organic electroluminescent layer), and the apertures WIN (the apertures of the bank 15) that constitute the above-mentioned three pixels PXLC. As illustrated, in the modification example 1-1, a color arrangement (R, G, and B) of the color filter layer 19 corresponds to a layout of the pixels PXLC, and the organic layer 16 includes a white light-emission layer (W) that is common to the three pixels PXLC. The apertures WIN of the bank 15 are provided in one-to-one correspondence with the pixels PXLC.

Also, in the modification example 1-1, as illustrated in FIG. 18, the organic layer 16 (the light-emission layer) includes, similarly to the above-described example embodiment, the yellow light-emission layer 16Y and the blue light-emission layer 16B. The lamination order of the yellow light-emission layer 16Y and the blue light-emission layer 16B may be inverted from as described above. The constituent material of the yellow light-emission layer 16Y is not limited to a material that configured to produce yellow (Y) light, but may be other material.

### Modification Example 1-2

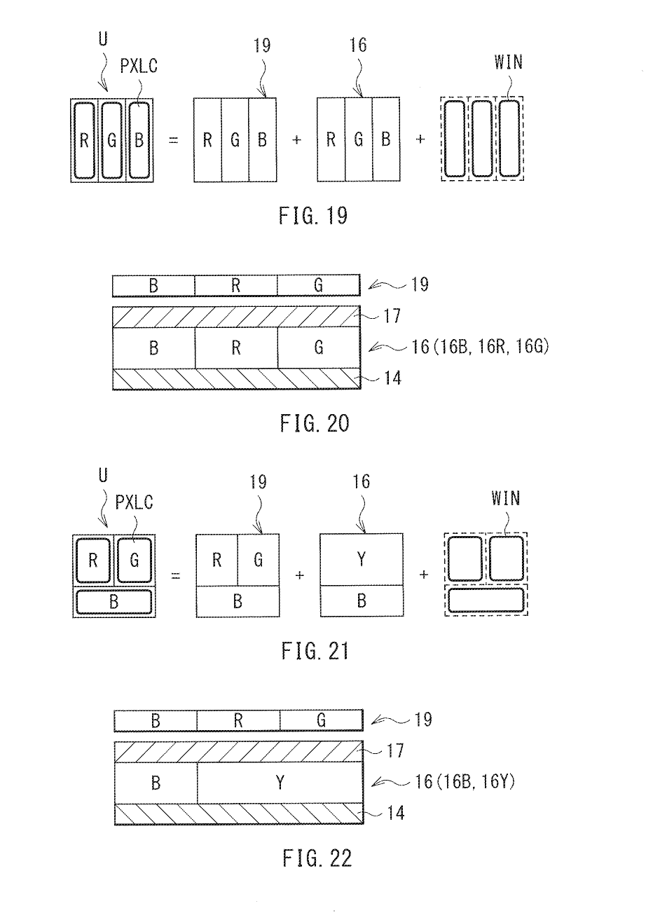

FIG. 19 illustrates an example of layouts of the color filter layer 19, the organic layer 16, and the apertures WIN that constitute the pixel PXLC according to a modification example 1-2. The modification example 1-2 is different from the above-described example embodiment in that the three pixels PXLC of R, G, and B constitute the display unit U, and that the organic layer 16 is formed separately for each color (that light-emission layers of different colors are formed for the respective pixels PXLC). In the modification example 1-2, as illustrated in FIG. 20, the organic layer 16 is provided with the light-emission layers of three colors (16R, 16G, and 16B) facing the respective regions of R, G, and B in the color filter layer 19.

In a case that, as mentioned above, the organic layer 16 is formed separately for each pixel PXLC, it is possible to increase a light-emission spectrum by an optical resonator effect utilizing a so-called micro cavity. In this case, for example, as the second electrode 17, a translucent conductive film such as magnesium-silver may be used. In this way, it is possible to allow color light produced in the organic layer 16 to resonate between the second electrode 17 and the first electrode 14 as a reflective electrode, increasing intensity of a desired wavelength.

### Modification Example 1-3

FIG. 21 illustrates an example of layouts of the color filter layer 19, the organic layer 16, and the apertures WIN that constitute the pixel PXLC according to a modification example 1-3. The modification example 1-3 is different from the above-described example embodiment in that the three pixels PXLC of R, G, and B constitute the display unit U, and that the organic layer 16 is formed separately for two colors, i.e. Y and B. In the modification example 1-3, as illustrated in FIG. 22, the organic layer 16 is provided with a yellow (Y) light-emission layer (the yellow light-emission layer 16Y) facing the regions of R and G in the color filter layer 19. The organic layer 16 is provided with a blue (B) light-emission layer (the blue light-emission layer 16B) facing the region of B in the color filter layer 19.

As mentioned above, the organic layer 16 may be formed separately for yellow (Y) in the region corresponding to the pixels PXLC of R and G, and blue (B) in the region corresponding to the pixel PXLC of B. Also in this case, similarly to the above-described modification example 1-2, it is possible to increase a light-emission spectrum by an optical resonator effect utilizing a micro cavity.

### Modification Example 1-4

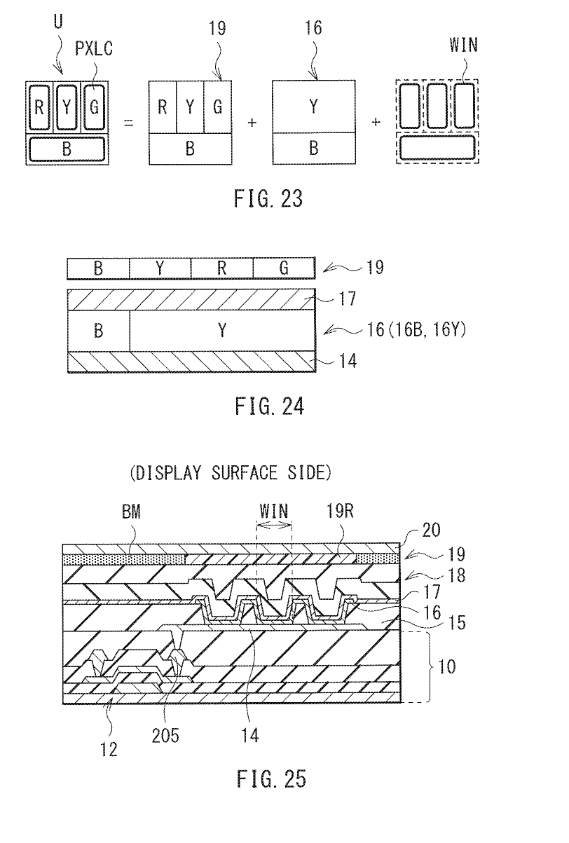

FIG. 23 illustrates an example of layouts of the color filter layer 19, the organic layer 16, and the apertures WIN that constitute the pixel PXLC according to a modification example 1-4. The modification example 1-4 is different from the above-described example embodiment in that the four pixels PXLC of R, G, B, and Y constitute the display unit U, and that the organic layer 16 is formed separately for two colors, i.e. Y and B. In the modification example 1-4, as illustrated in FIG. 24, the organic layer 16 is provided with the yellow light-emission layer 16Y in a region facing R, Y, and G in the color filter layer 19. The organic layer 16 is provided with the blue light-emission layer 16B in a region facing B in the color filter layer 19.

As mentioned above, the four pixels PXLC of R, G, B, and Y may constitute one pixel. In this case, the organic layer 16 may be formed separately so that the yellow light-emission layer 16Y is formed in a region corresponding to the pixels PXLC of R, Y, and G, and the blue light-emission layer 16B is formed in a region corresponding to the pixel PXLC of B. Also in this case, similarly to the above-described modification example 1-2, it is possible to increase a light-emission spectrum by an optical resonator effect utilizing a micro cavity.

### Modification Example 2

The above-described example embodiment exemplifies a configuration in which the apertures WIN of the bank 15 are provided in one-to-one correspondence with the pixels PXLC (the organic EL elements 10A). However, as in a modification example 2, a plurality of apertures WIN may be provided in one pixel PXLC to form a so-called reflector (an anode reflector). FIG. 25 illustrates, in section, a configuration of an element having an anode reflector according to the modification example 2. The modification example 2 is different from the example embodiment in that the bank 15 is provided with the plurality of apertures WIN in a part of a region where the first electrode 14 is formed. In an upper part of the first electrode 14 and the bank 15, the organic layer 16 is formed to cover the plurality of apertures WIN.

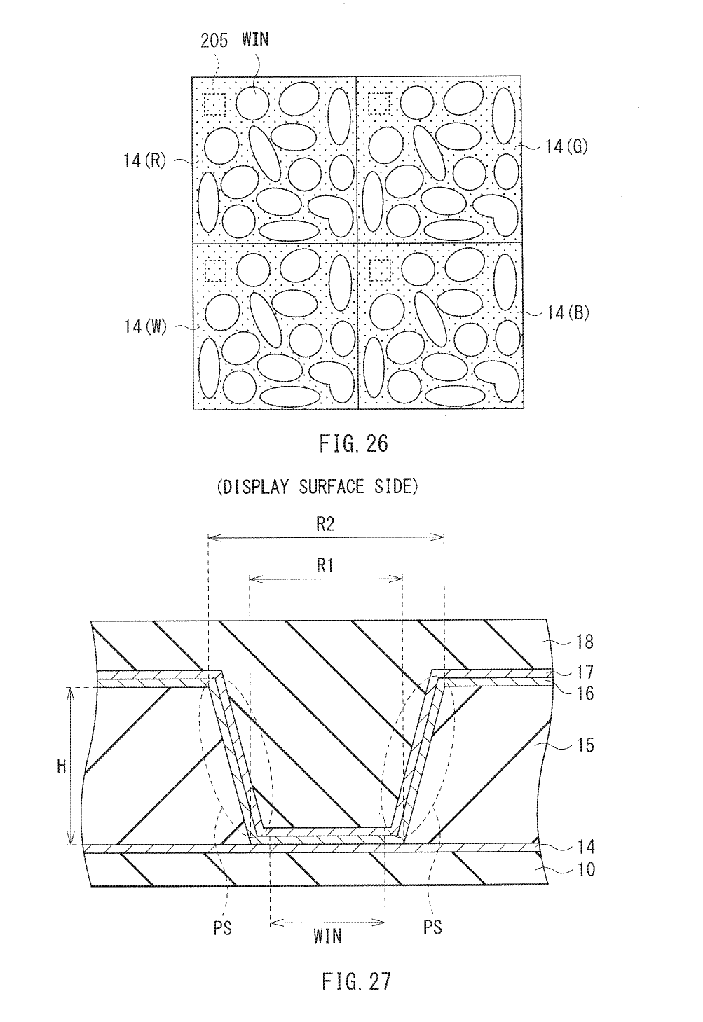

FIG. 26 illustrates a schematic arrangement of the apertures WIN on the first electrode 14. It is to be noted that the first electrodes 14(R), 14(G), 14(B), and 14(W) indicates anodes of the subpixels PXLC of R, G, B, and W. The first electrodes 14(R), 14(G), 14(B), and 14(W) (hereinbelow, simply referred to as the first electrode 14, if not particularly distinguished) are spaced from each other, though they are illustrated without any space between them for convenience in the figure. Each of the first electrodes 14 is connected to the drain of the transistor Tr1 for driving formed in the pixel drive circuit 140 through a contact 205. In the example here, the contact 205 is disposed at the upper left of each of the first electrodes 14.

Each of the first electrodes 14 is provided with the plurality of apertures WIN of various shapes in a random arrangement. Specifically, the apertures WIN have various shapes of, for example, a circle, an ellipse, a combined shape thereof, or the like. It is to be noted that an ellipse is not limited to an ellipse as strictly defined but also may simply refer to an elongated circle. The plurality of apertures WIN are arranged, on each of the first electrodes 14, without clear regularity, for example, without being arranged orderly in a predetermined direction. It is to be noted that, in the example here, the apertures WIN have substantially equal area to one another. In this way, it is possible to facilitate determining photolithography conditions in a manufacturing process. The apertures WIN are disposed at different positions from that of the contact 205. Also in the example here, the plurality of apertures WIN are arranged in the same pattern for all the first electrodes 14.

FIG. 27 illustrates, in section, a main part of the aperture WIN. Strictly, the aperture WIN is formed based on a design as follows. The bank 15 is formed with a thickness of a height H. An aperture width R1 of the bank 15 on the first electrode 14 side is smaller than an aperture width R2 on the display surface side. In other words, the bank 15 is provided with a sloped portion PS surrounding the aperture WIN. Thus, as described later, in the aperture WIN, light emitted from the organic layer 16 toward the sloped portion PS is reflected at the sloped portion PS due to a difference in refractive index between the bank 15 and the protective film (an insulating film) 18, and the reflected light proceeds in a front direction of the display surface. In this way, the sloped portion PS serves as a so-called reflector that is configured to reflect light emitted from the organic layer 16. Consequently, it is possible to improve, in each of the pixels PXLC, efficiency in extracting light externally. To allow the sloped portion PS to reflect light effectively, it is preferable that a refractive index (n1) of the protective film 18 and a refractive index (n2) of the bank 15 satisfy expressions as follows.

1.1≦n1≦1.8 (1)

n1−n2≧0.20 (2)

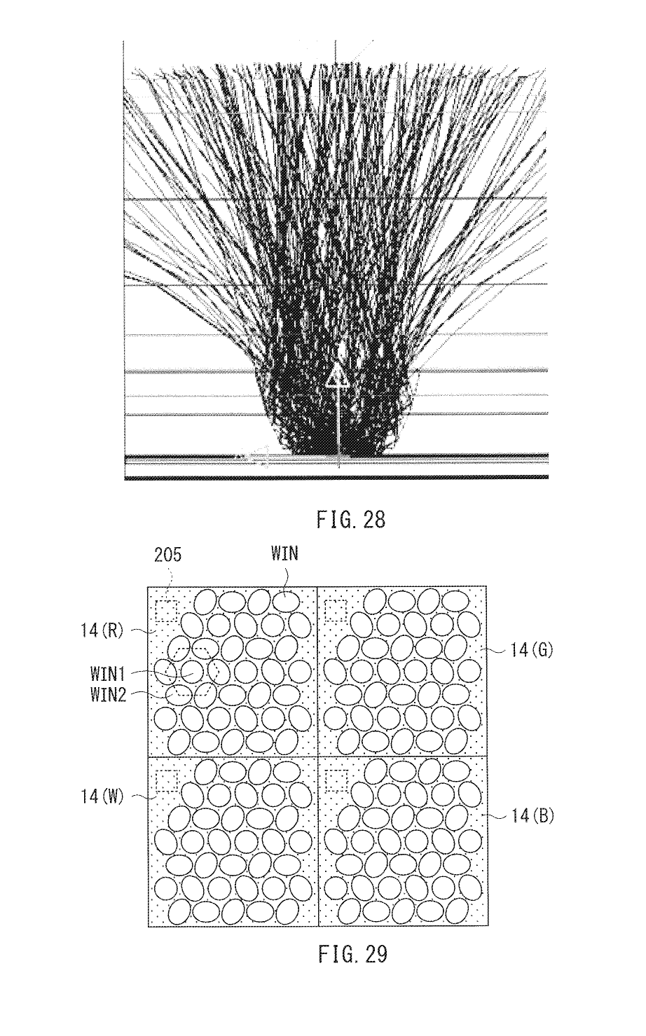

FIG. 28 illustrates an example of a simulation result of rays in the vicinity of the aperture WIN. FIG. 28 illustrates how light emitted downwardly from the organic layer 16 is reflected by a portion corresponding to the sloped portion PS to proceed upwardly. As illustrated, light after being reflected proceeds toward various directions. For example, some proceeds in a direction of a normal to the organic layer 16 (upwardly in FIG. 28), and some proceeds in a direction that is shifted from the normal direction (obliquely). A part of obliquely proceeding light enters the sloped portion PS to be reflected. Specifically, light is reflected at the sloped portion PS due to a difference in refractive index, since the bank 15 and the protective 18, which have different refractive indices from each other, are adjacent with the organic layer 16 and the second electrode 17 in between. The reflected light proceeds toward the display surface side to be extracted externally.

As described above, it is possible to improve efficiency in extracting light externally by the sloped portion PS of the aperture WIN. If no sloped portion PS is provided, there is a possibility that light emitted in a direction that is shifted from a direction normal to a light-emission layer 214 is attenuated in the display device or is shielded by a black matrix layer BM. In this case, a ratio of light extracted externally of the display device with respect to light emitted from the organic layer 16 is lowered, leading to lowered efficiency in extracting light externally. In the example embodiment 2, since the sloped portion PS is provided, it is possible to allow light to be reflected at the sloped portion PS, improving efficiency in extracting light externally. Moreover, the plurality of apertures WIN of various shapes are disposed in a random arrangement, it is possible to reduce a possibility of difficulty in viewing a display screen due to reflection of external light, improving image quality.

In the above-described example, the plurality of apertures WIN of various shapes are disposed in a random arrangement. However, the layout of the apertures WIN is not limited to the above-described example, but other various patterns may be adopted. In the following, some examples are given.

As illustrated in FIG. 29, the plurality of apertures WIN (WIN1 and WIN2) of various shapes may be disposed regularly in a predetermined pattern. In the example here, around a round aperture WIN1, six oval apertures WIN2 are disposed to surround the aperture WIN1. In other words, similarly to a so-called closest packed arrangement, three of the apertures WIN1 and WIN2 are arranged so as to be adjacent to one another. The six oval apertures WIN2 are arranged in different orientations from one another. Also in a case that the apertures WIN1 and WIN2 are arranged as mentioned above, it is possible to reduce a possibility of difficulty in viewing a display screen due to reflection of external light. Moreover, since the oval apertures WIN2 are arranged in different orientations from one another, it is possible to expand a view angle.

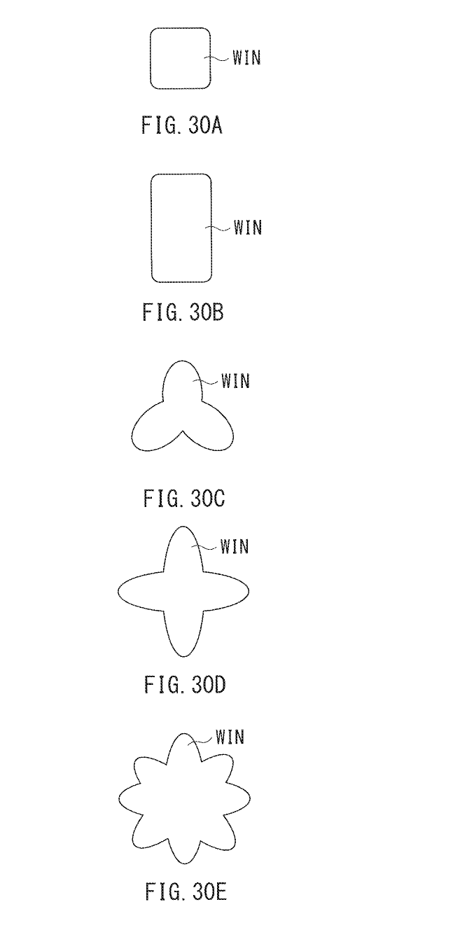

It is to be noted that, though in the example here the round apertures WIN1 and the oval apertures WIN2 are used, this is not limitative. Alternatively, apertures of various shapes as illustrated in FIGS. 30A to 30E may be used. Specifically, for example, the aperture WIN may have a shape of a rounded square as illustrated in FIG. 30A, or a shape of a rounded rectangular as illustrated in FIG. 30B, or a shape of a combination of a plurality of ellipses as illustrated in FIGS. 30C to 30E.

Alternatively, as illustrated in FIG. 31, the number of apertures (WIN3) provided in the pixel PXLC for white may be smaller than that of the apertures provided in the pixels for other colors. On the first electrodes 14(R), 14(G), and 14(B), similarly to the above-described example as illustrated in FIG. 26, the plurality of apertures WIN of various shapes are disposed in a random arrangement. On the other hand, on the first electrodes 14(W), a large aperture WIN3 in the example here is disposed.

In this configuration, it is possible to restrain diffraction of external light in the pixel PXLC for white, lowering a possibility of difficulty in viewing a display screen due to reflected light. Since the pixel PXLC for white is provided with the white color filter 19W that allows light of a wide wavelength range to pass through, external light (in white) is allowed to pass through the color filter 19W to enter inside. Therefore, in a case of occurrence of diffraction in the pixel PXLC for white, light tends to be reflected over a large region, causing difficulty in viewing a display screen. Since, in the modification example 2, the pixel PXLC for white is provided with a single aperture WIN3, it is possible to restrain occurrence of diffraction.

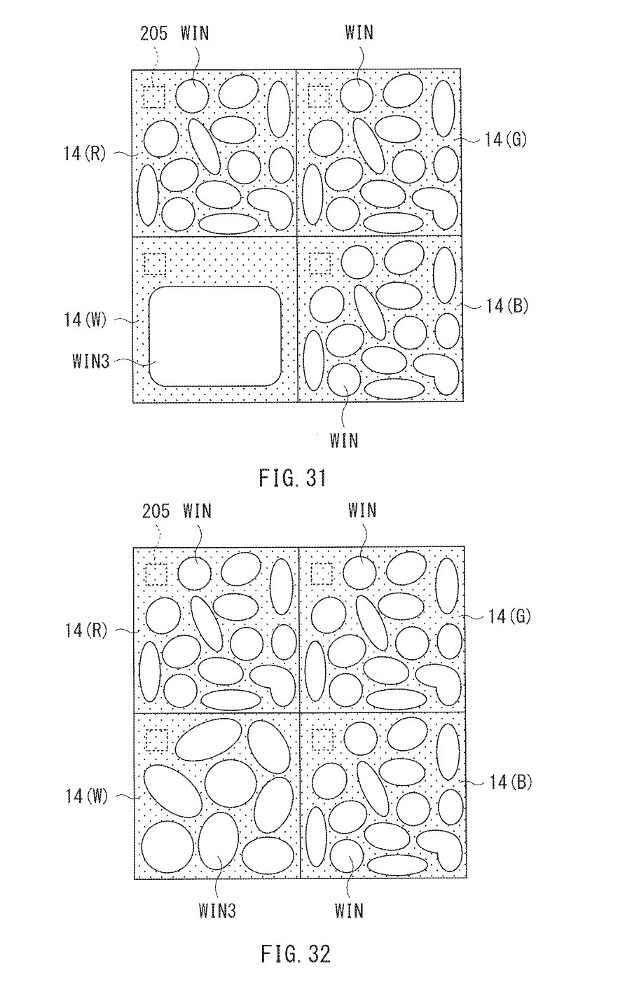

It is to be noted that the number of the aperture WIN3 in the pixel PXLC for white is not limited to one. As illustrated in FIG. 32, the plurality of apertures WIN3 may be provided, and the number of apertures WIN3 may be fewer than the number of the apertures in the pixels PXLC for other colors. In this case, for improving aperture rate, each of the apertures WIN3 has preferably large area.

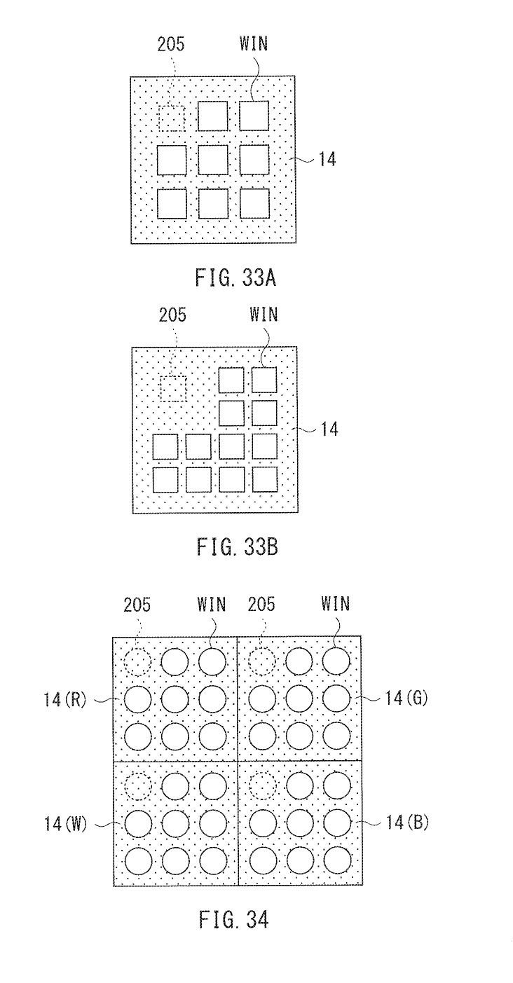

Further, as illustrated in FIGS. 33A and 33B, the apertures WIN may have a quadrangle shape such as a square, a rectangle or the like.

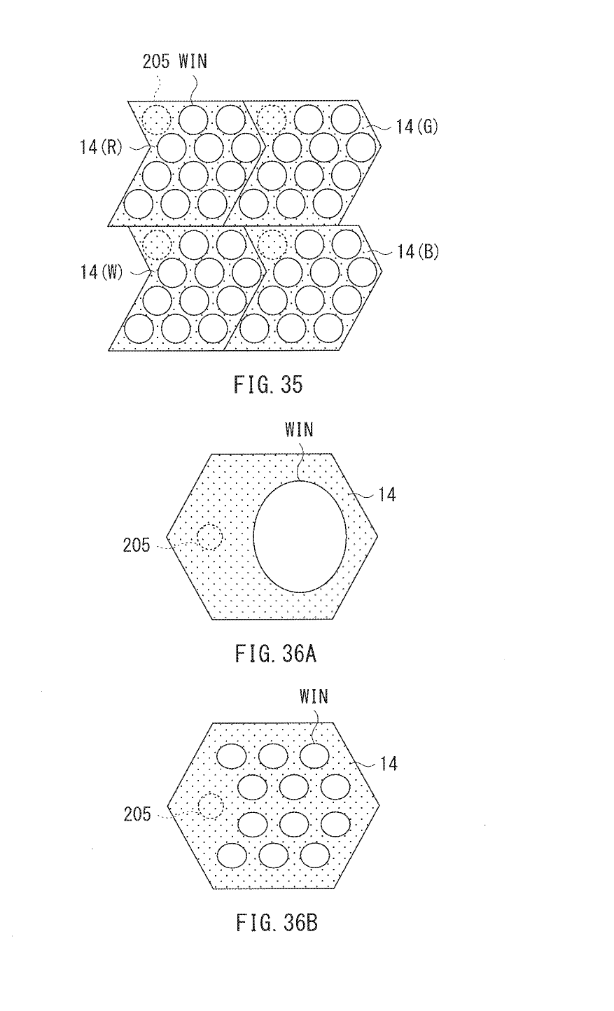

In addition, as illustrated in FIGS. 34 and 35, the contact 205 may have a round shape of the substantially same size as the aperture WIN. In this case, it is possible to arrange the contact 205 and the apertures WIN more effectively within limited area. Also as illustrated in FIG. 35, the contact 205 and the apertures WIN may be in a so-called closest packed arrangement. In the closest packed arrangement here, for example, three apertures WIN are disposed adjacently to one another. Thus, it is possible to arrange the contact 205 and the apertures WIN even more effectively. In this case, the sides of the first electrode 14, which defines an outline of the first electrode 14, are provided in a gap between the contact 205 and the apertures WIN. In this way, in the example here, an upper side and a lower side of the first electrode 14 extend in a lateral direction, while two left sides and two right sides each constitute a V shape in the alphabet, with each side extending in a direction that shifts from the lateral direction by 60°.

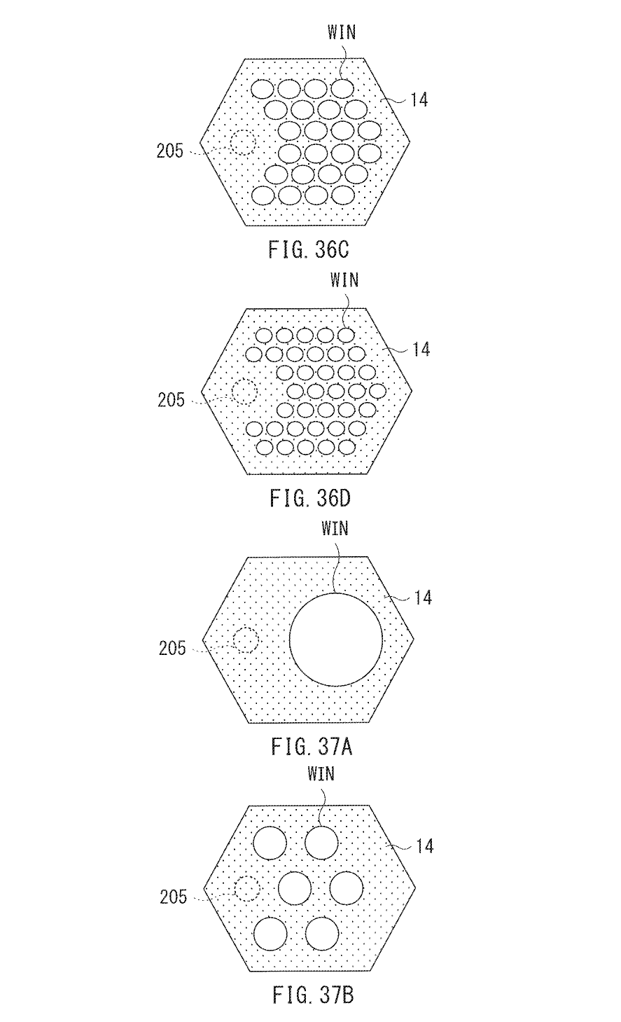

Alternatively, as illustrated in FIGS. 36A to 36D, FIGS. 37A to 37F, and FIGS. 38A and 38B, the first electrode 14 may have a shape of, for example, a horizontally(laterally)-elongated hexagon. Thus, it is possible to secure larger area of the first electrode 14. Moreover, it is possible to arrange the plurality of apertures WIN effectively in each region over the first electrode 14. Specifically, in a case that the first electrode 14 has a shape of a horizontally-enlarged regular hexagon, the aperture WIN may have a shape of an ellipse obtained by enlarging a circle at the same ratio as an enlargement ratio of the first electrode 14. Thus, a closest packed arrangement is easily obtained. However, the number of the apertures WIN may be one, or the apertures WIN may be smaller in density than a closest packed arrangement.

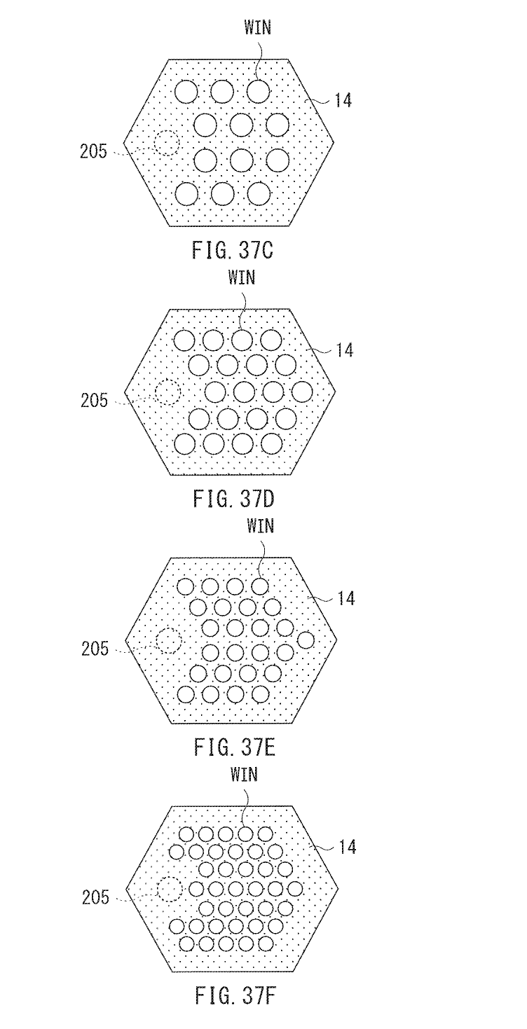

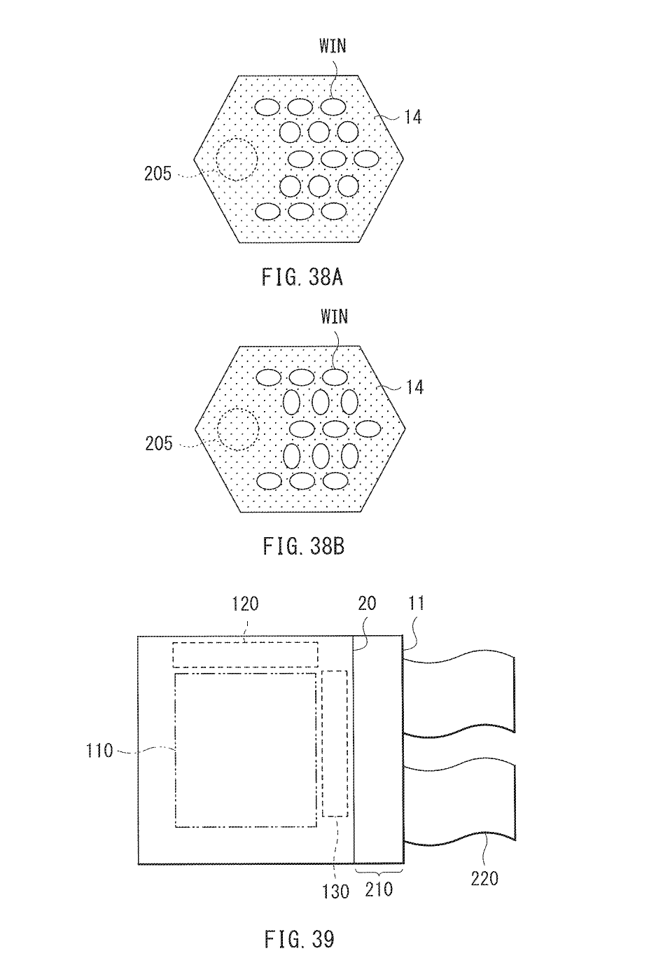

It is to be noted that, in FIG. 36D, the apertures WIN are provided in seven rows. As illustrated, in a case that the apertures WIN are provided in an odd-number of rows, it is possible to dispose all the apertures WIN in a closest packed arrangement. However, as illustrated in FIGS. 36B and 36C, even in a case that the apertures WIN are provided in an even number of rows, the apertures WIN in an upper region may be disposed in a closest packed arrangement, while the apertures WIN in a lower region may be disposed in a closest packed arrangement. Alternatively, as illustrated in FIGS. 37A to 37F, the aperture WIN may have a round shape. Alternatively, as illustrated in FIG. 38A, both the oval apertures WIN and the round apertures WIN may be provided. Alternatively, as illustrated in FIG. 38B, both the vertically-long oval apertures WIN and the laterally-long oval apertures WIN may be provided. In this case, it is possible to expand a view angle in an up-and-down direction as well as a left-and-right direction.

### Application Examples

The display device as described in the above example embodiment and modification examples may be applied to an electronic apparatus in various fields that is configured to display a picture based on a picture signal input from outside or a picture signal generated inside. The display device is incorporated, in a form of a module as illustrated in FIG. 39, in an electronic apparatus such as a television set, a digital camera, a video camera, a notebook personal computer, a mobile phone and a smart phone, which are exemplified in the following. In FIG. 39, on the substrate 11, provided are the display region 110, and the signal line drive circuit 120 and the scan line drive circuit 130 and so on. The display region 110 includes, for example, the subpixels (the pixels PXLC including the above-described organic EL elements 10A) arranged in a two-dimensional array. Along one side of the substrate 11, provided is a region 210 exposed from the sealing substrate 20. In the region 210, provided are external connection terminals (not illustrated) that are extended from wirings of the signal line drive circuit 120 and the scan line drive circuit 130. On the external connection terminals, provided is a flexible printed circuit (FPC) 220 for signal input and output.

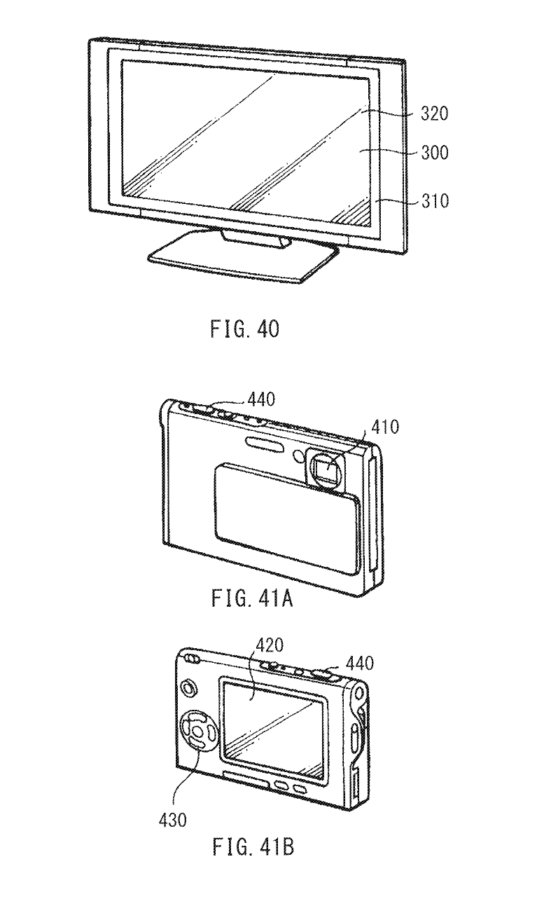

FIG. 40 illustrates an appearance of a television set. The television set includes, for example, a picture display screen section 300 that includes a front panel 310 and a filter glass 320. The picture display screen section 300 is configured of the display device according to the above-described embodiment and so on.

FIGS. 41A and 41B illustrate an appearance of a digital camera. The digital camera includes, for example, a lighting section for flash lighting 410, a display section 420, a menu switch 430, and a shutter button 440. The display section 420 is configured of the display device according to the above-described embodiment and so on.

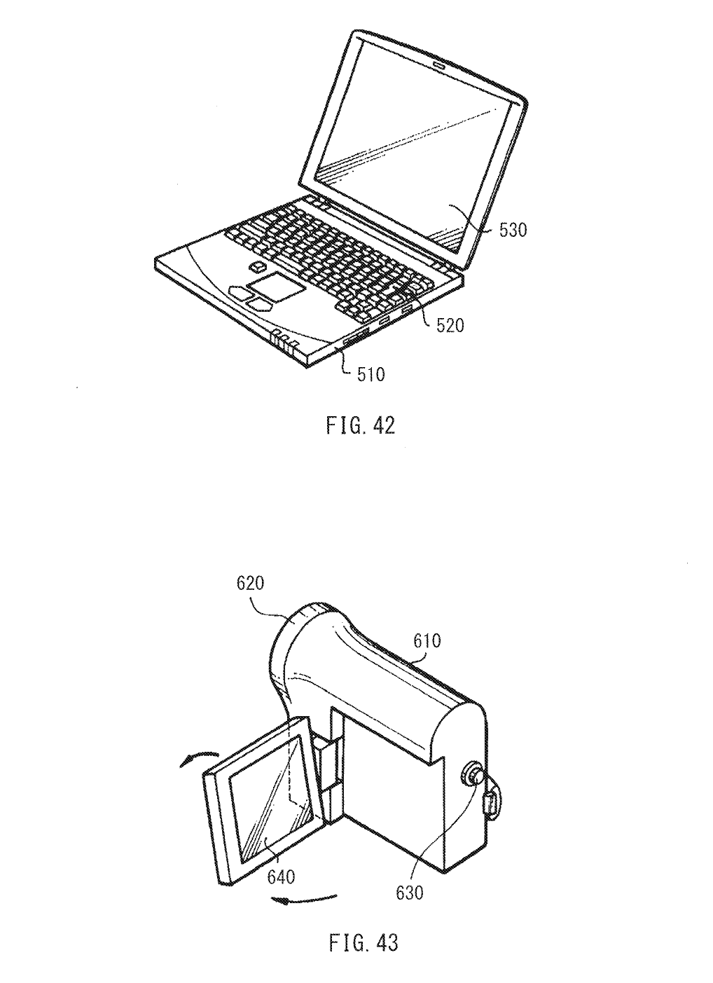

FIG. 42 illustrates an appearance of a notebook personal computer. The notebook personal computer includes, for example, a main body 510, a keyboard 520 for input operations of characters and the like, and a display section 530 for image display. The display section 530 is configured of the display device according to the above-described embodiment and so on.

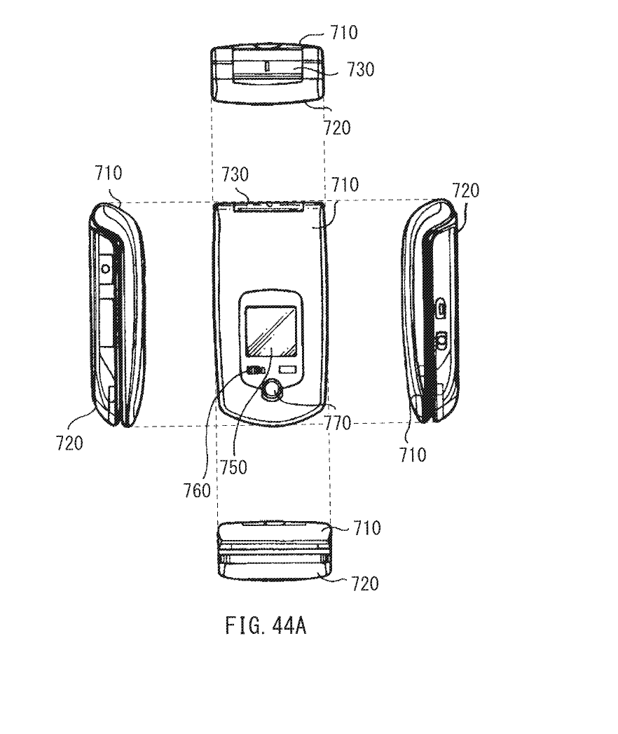

FIG. 43 illustrates an appearance of a video camera. The video camera includes, for example, a main body 610, a lens 620 for photographing an object, which is provided on a front side face of the main body 610, a start/stop switch 630 in photographing, and a display section 640. The display section 640 is configured of the display device according to the above-described embodiment and so on.

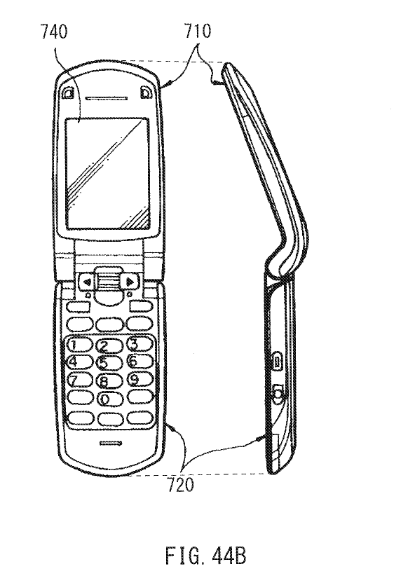

FIGS. 44A and 44B illustrate an appearance of a mobile phone. The mobile phone has a configuration, for example, in which an upper casing 710 and a lower casing 720 are linked by a connection section (a hinge section) 730, and includes a display 740, a sub-display 750, a picture light 760, and a camera 770. The display 740 or the sub-display 750 is configured of the display device according to the above-described embodiment and so on.

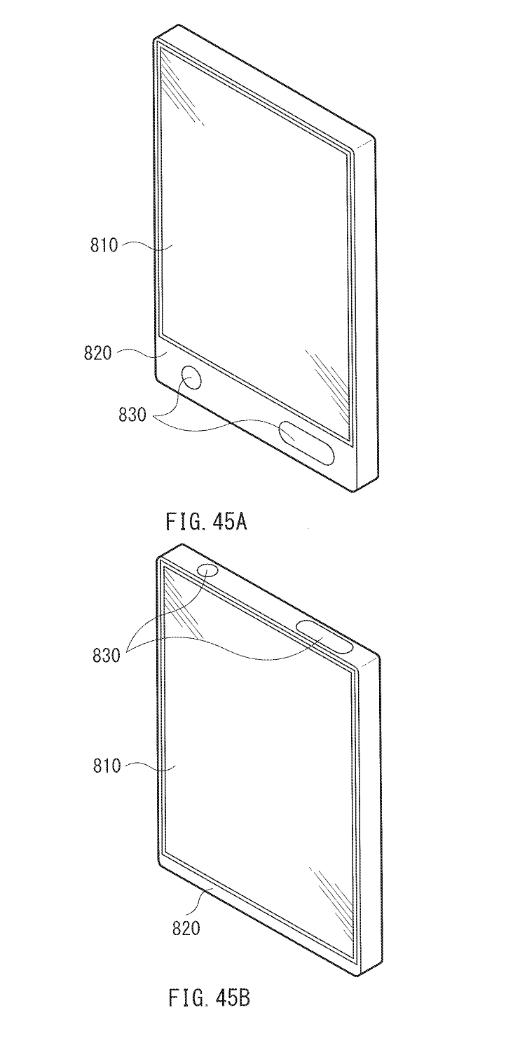

FIGS. 45A and 45B illustrate an appearance of a smart phone. The smart phone includes, for example, a display section 810 and a non-display section (a casing) 820, and an operation section 830. The operation section 830 may be provided either on a front face (FIG. 45A) or on a top face (FIG. 45B) of the non-display section 820. The display section 810 is configured of the display device according to the above-described embodiment and so on.

Although description has been made by giving the example embodiment and the modification examples as mentioned above, the contents of the present disclosure are not limited to the above-mentioned embodiments and so forth and may be modified in a variety of ways. For example, in the repair operation, the reverse bias voltage may be applied to a selective region that is to be a dark spot, but this is not limitative. Alternatively, the reverse bias voltage may be applied to a large region including a portion of a dark spot. The latter method contributes to shortened time for the repair operation, and is advantageous in mass-production. It is to be noted that the reverse bias voltage may be applied to a normal region, but it is possible to enjoy an effect of improving repair efficiency by controlling application conditions appropriately.

Moreover, in the above-described embodiments and so forth, an example of the two-layered second electrode 17 is given. However, the second electrode 17 may be a multi-layered film of three or more layers including other conductive films.

Further, a material and a thickness of each layer as described in the above-mentioned embodiments and so forth are not limited to as exemplified above, but other materials or other thicknesses may be adopted. In addition, in the display device, it is not necessary to include all the layers described above, and rather a layer or layers other than the above-mentioned layers may be also included. It is to be noted that effects described in the above-described embodiments and so forth are merely exemplified and not limitative, and effects of the present disclosure may be other effects or may further include other effects.

It is possible to achieve at least the following configurations from the above-described example embodiments of the disclosure.

(1) A display device, including:

a first electrode;

an organic layer that is provided on the first electrode and includes a light-emission layer; and

a second electrode that includes a first conductive film and a second conductive film, the first conductive film and the second conductive film being laminated in order on the organic layer.

(2) The display device according to (1), wherein a thickness of the first conductive film is smaller than a thickness of the second conductive film.
(3) The display device according to (2), wherein the thickness of the first conductive film is equal to or smaller than one tenth of the thickness of the second conductive film.
(4) The display device according to any one of (1) to (3), wherein the first conductive film and the second conductive film have light-transmittance.
(5) The display device according to (4), wherein the first conductive film includes a local portion having higher resistance than that of another portion.
(6) The display device according to (4) or (5), wherein the first conductive film and the second conductive film are configured of a same material.
(7) The display device according to (6), wherein the first conductive film and the second conductive film are configured of indium zinc oxide (IZO).
(8) The display device according to (4) or (5), wherein

the first conductive film includes an alloy of magnesium (Mg) and silver (Ag), and

the second conductive film includes indium zinc oxide (IZO).

(9) The display device according to any one of (1) to (8), further including an oxide film that is interposed between the first conductive film and the second conductive film.
(10) The display device according to any one of (1) to (3), wherein

the first conductive film is a transparent conductive film, and

the second conductive film is a metal film having light-reflectivity.

(11) An electronic apparatus provided with a display device, the display device including:

a first electrode;

an organic layer that is provided on the first electrode and includes a light-emission layer; and

a second electrode that includes a first conductive film and a second conductive film, the first conductive film and the second conductive film being laminated in order on the organic layer.

(12) A display device, including:

a first electrode;

an organic layer that is provided on the first electrode and includes a light-emission layer; and

a second electrode that is provided on the organic layer and includes a local portion having higher resistance than that of another portion.

(13) The display device according to (12), wherein

the second electrode includes a first conductive film and a second conductive film, the first conductive film and the second conductive film being laminated in order on the organic layer, and

the local portion is provided in the first conductive film.

It should be understood by those skilled in the art that various modifications, combinations, sub-combinations and alterations may occur depending on design requirements and other factors insofar as they are within the scope of the appended claims or the equivalents thereof.

What is claimed is:

1. A display device, comprising:
a first electrode;
an organic layer that is provided on the first electrode and includes a light-emission layer; and
a second electrode that includes a first conductive film and a second conductive film, the first conductive film and the second conductive film being laminated in order on the organic layer.

2. The display device according to claim 1, wherein a thickness of the first conductive film is smaller than a thickness of the second conductive film.

3. The display device according to claim 2, wherein the thickness of the first conductive film is equal to or smaller than one tenth of the thickness of the second conductive film.

4. The display device according to claim 1, wherein the first conductive film and the second conductive film have light-transmittance.

5. The display device according to claim 4, wherein the first conductive film includes a local portion having higher resistance than that of another portion.

6. The display device according to claim 4, wherein the first conductive film and the second conductive film are configured of a same material.

7. The display device according to claim 6, wherein the first conductive film and the second conductive film are configured of indium zinc oxide (IZO).

8. The display device according to claim 4, wherein
the first conductive film includes an alloy of magnesium (Mg) and silver (Ag), and
the second conductive film includes indium zinc oxide (IZO).

9. The display device according to claim 1, further comprising an oxide film that is interposed between the first conductive film and the second conductive film.

10. The display device according to claim 1, wherein
the first conductive film is a transparent conductive film, and
the second conductive film is a metal film having light-reflectivity.

11. An electronic apparatus provided with a display device, the display device comprising:
a first electrode;
an organic layer that is provided on the first electrode and includes a light-emission layer; and
a second electrode that includes a first conductive film and a second conductive film, the first conductive film and the second conductive film being laminated in order on the organic layer.

12. A display device, comprising:
a first electrode;
an organic layer that is provided on the first electrode and includes a light-emission layer; and
a second electrode that is provided on the organic layer and includes a local portion having higher resistance than that of another portion.

13. The display device according to claim 12, wherein
the second electrode includes a first conductive film and a second conductive film, the first conductive film and the second conductive film being laminated in order on the organic layer, and
the local portion is provided in the first conductive film.
